(19) United States
(12) Patent Application Publication
(10) Pub. No.: US 2025/0008739 A1
(43) Pub. Date: Jan. 2, 2025

(54) MEMORY ELEMENT AND MEMORY DEVICE

(71) Applicant: SEMICONDUCTOR ENERGY LABORATORY CO., LTD., Atsugi-shi, Kanagawa-ken (JP)

(72) Inventors: Haruyuki BABA, Isehara, Kanagawa (JP); Hitoshi KUNITAKE, Machida, Tokyo (JP)

(21) Appl. No.: 18/707,987

(22) PCT Filed: Nov. 4, 2022
(86) PCT No.: PCT/IB2022/060624

§ 371 Date: May 7, 2024

(30) Foreign Application Priority Data
Nov. 18, 2021 (JP) 2021-188016

(51) Int. Cl. H10B 51/30

(52) U.S. Cl. CPC H10B 51/30

(57) ABSTRACT

A memory element with a novel structure is provided. The memory element includes a stack of a first electrode, a first insulating layer, a semiconductor layer, a second insulating layer, and a second electrode. The first electrode, the first insulating layer, the semiconductor layer, the second insulating layer, and the second electrode include a region where they overlap with each other. An oxide semiconductor, which is a kind of a metal oxide, is used for the semiconductor layer. For the first insulating layer, a material having anti-ferroelectricity is used.

### TECHNICAL FIELD

One embodiment of the present invention relates to memory element and a memory device.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter.

Thus, examples of the technical field of one embodiment of the present invention include a semiconductor device, a display device, a liquid crystal display device, a light-emitting device, a power storage device, an imaging device, a memory device, a signal processing device, a processor, an electronic device, a system, a driving method thereof, a manufacturing method thereof, a testing method thereof, and a usage method thereof.

### BACKGROUND ART

In recent years, semiconductor devices such as LSI, CPUs, and memories (memory devices) have been developed. These semiconductor devices have been used in various electronic devices such as computers and portable information terminals. In addition, memories under development employ various memory systems for intended uses such as temporary storage at the time of executing arithmetic processing and long-term storage of data. Examples of memories with typical memory systems include a DRAM, an SRAM, and a flash memory.

Memories using ferroelectrics have been actively researched and developed as disclosed in Non-Patent Document 1. For the next-generation ferroelectric memories, researches on hafnium oxide, such as research on ferroelectric HfO₂-based materials (Non-Patent Document 2); research on ferroelectricity of a hafnium oxide thin film (Non-Patent Document 3); research on ferroelectricity of a HfO₂ thin film (Non-Patent Document 4); and demonstration of integration of an FeRAM using a ferroelectric Hf_{0.5}Zr_{0.5}O₂ and a CMOS (Non-Patent Document 5) have been actively carried out.

Patent Document 1 discloses a structure of an MFSFET (Metal Ferroelectric Semiconductor Field Effect Transistor), which is a kind of an FeFET (Ferroelectric Field Effect Transistor) using a ferroelectric material as a gate insulating film, in which the gate insulating film is provided in contact with an oxide where a channel is formed.

### REFERENCE

### Patent Document

[Patent Document 1] Japanese Published Patent Application No. H7-326683

### Non-Patent Document

[Non-Patent Document 1] T. S. Boescke, et al, “Ferroelectricity in hafnium oxide thin films”, APL99, 2011
[Non-Patent Document 2] Zhen Fan, et al, “Ferroelectric HfO₂-based materials for next-generation ferroelectric memories”, JOURNAL OF ADVANCED DIELECTRICS, Vol. 6, No. 2, 2016
[Non-Patent Document 3] Jun Okuno, et al, “SoC compatible 1T1C FeRAM memory array based on ferroelectric Hf_{0.5}Zr_{0.5}O₂”, VLSI 2020
[Non-Patent Document 4] Akira Toriumi, “Ferroelectric properties of thin HfO₂ films”, the Japan Society of Applied Physics, Vol. 88, No. 9, 2019
[Non-Patent Document 5] T. Francois, et al, “Demonstration of BEOL-compatible ferroelectric Hf_{0.5}Zr_{0.5}O₂ scaled FeRAM co-integrated with 130 nm CMOS for embedded NVM applications”, IEDM 2019

### SUMMARY OF THE INVENTION

### Problems to be Solved by the Invention

In recent years, the amount of data handled by electronic devices tends to increase, so that an increase in memory capacity is required. For example, an FeFET described in Patent Document 1 cannot retain three-level or more data; thus, it is difficult to increase a memory capacity of a memory device using the FeFET.

An object of one embodiment of the present invention is to provide a memory element or a memory device with high memory capacity. Another object is to provide a memory element or a memory device that occupies a small area. Another object is to provide a memory element or a memory device with high reliability. Another object is to provide a memory element or a memory device with low power consumption. Another object is to provide a novel memory element or a memory device. Another object of one embodiment of the present invention is to provide a semiconductor device with high memory capacity. Another object is to provide a semiconductor device that occupies a small area. Another object is to provide a highly reliable semiconductor device. Another object is to provide a semiconductor device with low power consumption. Another object is to provide a novel semiconductor device.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

One embodiment of the present invention is a memory element including a first electrode that includes a region overlapping with a semiconductor layer with a first insulating layer therebetween and a second electrode that includes a region overlapping with the semiconductor layer with a second insulating layer therebetween. The first electrode and the second electrode include a region where they overlap with each other with the first insulating layer, the semiconductor layer, and the second insulating layer therebetween. The semiconductor layer contains an oxide semiconductor. The first insulating layer has anti-ferroelectricity.

Another embodiment of the present invention is a memory element including a first electrode that includes a region overlapping with a first region of a semiconductor layer with a first insulating layer therebetween, a second electrode that includes a region overlapping with the first region with a second insulating layer therebetween, a third electrode electrically connected to a second region of the semiconductor layer, and a fourth electrode electrically connected to a third region of the semiconductor layer. The first electrode and the second electrode include a region where they overlap with each other with the first insulating layer, the first region, and the second insulating layer therebetween. The semiconductor layer contains an oxide semiconductor. The first insulating layer has anti-ferroelectricity.

The semiconductor layer preferably contains at least one of indium and zinc. The first insulating layer preferably contains hafnium and preferably contains hafnium and zirconium.

The semiconductor layer preferably contains at least one of hydrogen, nitrogen, phosphorus, fluorine, chlorine, and a noble gas.

Another embodiment of the present invention is a memory device including a memory array that includes the memory elements described above and a driver circuit.

### Effect of the Invention

One embodiment of the present invention can provide a memory element or a memory device with high memory capacity. A memory element or a memory device that occupies a small area can be provided. A memory element or a memory device with high reliability can be provided. A memory element or a memory device with low power consumption can be provided. A novel memory element or a memory device can be provided. A semiconductor device with high memory capacity can be provided. A semiconductor device that occupies a small area can be provided. A highly reliable semiconductor device can be provided. A semiconductor device with low power consumption can be provided. A novel semiconductor device can be provided.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A is an equivalent circuit diagram of a semiconductor device. FIG. 1B is a schematic cross-sectional view illustrating a structure example of a transistor. FIG. 1C is a graph showing an example of hysteresis characteristics.

FIG. 2A and FIG. 2B are graphs each showing an example of hysteresis characteristics.

FIG. 3 is a diagram illustrating crystal structures of hafnium oxide.

FIG. 4A and FIG. 4B are diagrams illustrating a model of an orthorhombic crystal structure of HfZrOₓ.

FIG. 5 is a graph showing an example of hysteresis characteristics.

FIG. 6A to FIG. 6D are schematic cross-sectional views of a transistor. FIG. 6E is a diagram showing examples of Id-Vg characteristics of the transistor.

FIG. 7A is a timing chart illustrating operation of a semiconductor device. FIG. 7B is a circuit diagram illustrating the operation of the semiconductor device.

FIG. 8A is a timing chart illustrating operation of a semiconductor device. FIG. 8B is a circuit diagram illustrating the operation of the semiconductor device.

FIG. 9A is a timing chart illustrating operation of a semiconductor device. FIG. 9B is a circuit diagram illustrating the operation of the semiconductor device.

FIG. 10A is a timing chart illustrating operation of a semiconductor device. FIG. 10B is a circuit diagram illustrating the operation of the semiconductor device.

FIG. 11A is a block diagram illustrating a structure example of a semiconductor device. FIG. 11B is a perspective view illustrating a structure example of the semiconductor device.

FIG. 12A to FIG. 12C are diagrams illustrating a structure example of a transistor.

FIG. 13A and FIG. 13B are perspective views illustrating examples of electronic components.

FIG. 14A to FIG. 14J are diagrams illustrating examples of electronic devices.

FIG. 15A to FIG. 15E are diagrams illustrating examples of electronic devices.

FIG. 16A to FIG. 16C are diagrams illustrating examples of electronic devices.

### MODE FOR CARRYING OUT THE INVENTION

Embodiments are described below with reference to the drawings. Note that the embodiments can be implemented in many different modes, and it is readily understood by those skilled in the art that modes and details can be changed in various ways without departing from the spirit and scope. Thus, the present invention should not be interpreted as being limited to the following description of the embodiments.

In this specification, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, an electronic device, and the like themselves might be semiconductor devices, or might include semiconductor devices.

In the drawings and the like in this specification, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings.

Note that in the structures of the invention in the embodiments, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases. Moreover, some components are omitted in a perspective view, a top view; and the like for easy understanding of the drawings in some cases.

Note that arrows indicating the X direction (direction along the X-axis), the Y direction (direction along the Y-axis), and the Z direction (direction along the Z-axis) are sometimes illustrated in the drawings and the like. Note that in this specification and the like, “X direction” is a direction along the X axis, and the forward direction and the reverse direction are not distinguished from each other unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. As another example, a “first” component in one embodiment in this specification and the like can be omitted in other embodiments or the scope of claims.

In this specification and the like, the terms for describing positioning, such as “over”, “under” “above”, and “below”, are sometimes used for convenience to describe the positional relation between components with reference to drawings. The positional relation between components is changed as appropriate in accordance with the direction in which the components are described. Thus, the positional relation is not limited to the terms described in this specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “the electrode B overlapping with the insulating layer A” is not limited to the state where “the electrode B is formed over the insulating layer A”, and does not exclude the state where “the electrode B is formed under the insulating layer A”, the state where “the electrode B is formed on the right side (or the left side) of the insulating layer A”, the state where “the electrode B is formed on the front side (or the back side) of the insulating layer A”, and the like.

Each of the terms “adjacent” and “proximity” in this specification and the like does not necessarily mean that a component is directly in contact with another component. For example, the expression “the electrode B adjacent to the insulating layer A” does not necessarily mean that the electrode B is formed in direct contact with the insulating layer A and does not exclude the state where another component (including a space) exists between the insulating layer A and the electrode B.

In this specification and the like, the terms “film”, “layer”, and the like can be interchanged with each other depending on the situation. For example, the term “conductive layer” can be replaced with the term “conductive film” in some cases. For another example, the term “insulating film” can be replaced with the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. Alternatively, the term “conductor” can be changed into the term “conductive layer” or “conductive film” in some cases. As another example, the term “insulating layer” or “insulating film” can be changed into the term “insulator” in some cases. Alternatively, the term “insulator” can be changed into the term “insulating layer” or “insulating film” in some cases.

Note that voltage refers to a difference between potentials of two points, and a potential refers to electrostatic energy (electric potential energy) of a unit charge at a given point in an electrostatic field. Note that in general, a potential difference between a potential at a given point and a reference potential (e.g., a ground potential) is simply called potential or voltage, and potential and voltage are used as synonymous words in many cases. Therefore, in this specification and the like, potential is interchangeable with voltage and voltage is interchangeable with potential unless explicitly stated.

In this specification and the like, the term “electrode”, “wiring”, “terminal”, or the like does not limit the function of a component. For example, an “electrode” is used as part of a “wiring” in some cases, and vice versa. Furthermore, for example, the term “electrode” or “wiring” also includes the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the terms “electrode”, “wiring”, “terminal”, and the like are sometimes replaced with the term “region” or the like depending on the case.

In this specification and the like, the terms “wiring”, “signal line”, “power supply line”, and the like can be interchanged with each other depending on the case or the situation. For example, the term “wiring” can be changed into the term “signal line” in some cases. For another example, the term “wiring” can be changed into the term “power supply line” or the like in some cases. Conversely, the term “signal line”, “power supply line”, or the like can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on the case or the situation. Conversely, the term “signal” or the like can be changed into the term “potential” in some cases.

Note that in this specification and the like, a gate refers to part or all of a gate electrode and a gate wiring. A gate wiring refers to a wiring electrically connected to a gate electrode of at least one transistor.

A source refers to part or all of a source region, a source electrode, or a source wiring. A source region refers to a region in a semiconductor layer where the resistivity is lower than or equal to a given value. A source electrode refers to a conductive layer including part connected to a source region. A source wiring refers to a wiring electrically connected to a source electrode of at least one transistor.

A drain refers to part or all of a drain region, a drain electrode, or a drain wiring. A drain region refers to a region in a semiconductor layer where the resistivity is lower than or equal to a given value. A drain electrode refers to a conductive layer including part connected to a drain region. A drain wiring refers to a wiring electrically connected to a drain electrode of at least one transistor.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the terms “identical”, “the same”, “equal”, “uniform”, and the like (including synonyms thereof) used in describing calculation values and measurement values contain an error of ±20% unless otherwise specified.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, a conductive layer 242 is divided and shown as a conductive layer 242a and a conductive layer 242b in some cases.

### Embodiment 1

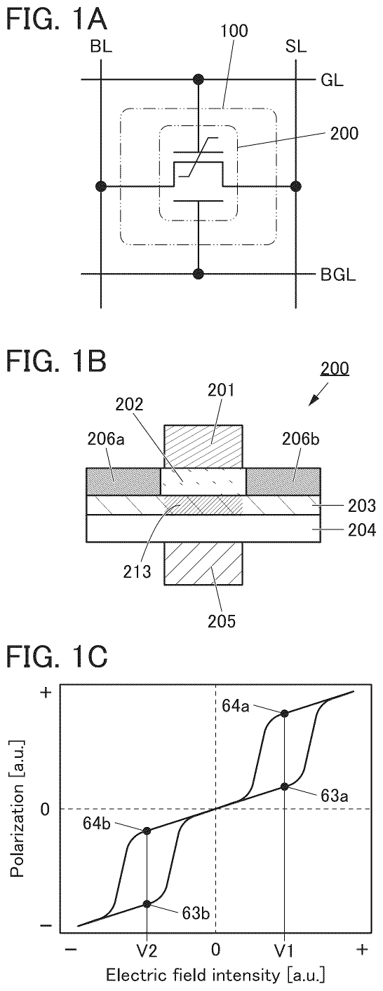

A semiconductor device 100 of one embodiment of the present invention will be described. FIG. 1A is an equivalent circuit diagram of the semiconductor device 100. The semiconductor device 100 functions as a memory element (“memory cell”) including a transistor 200. FIG. 1B is a schematic cross-sectional view illustrating a structure example of the transistor 200.

The transistor 200 is a field effect transistor including a back gate. A gate of the transistor 200 is electrically connected to a wiring GL, and the back gate thereof is electrically connected to a wiring BGL (see FIG. 1A). One of a source and a drain of the transistor 200 is electrically connected to a wiring BL, and the other thereof is electrically connected to a wiring SL.

The transistor 200 includes a conductive layer 201 functioning as a gate, a dielectric layer 202 functioning as a gate insulating layer, a semiconductor layer 203 functioning as a semiconductor layer where a channel is formed, a dielectric layer 204 functioning a gate insulating layer on a back gate side, a conductive layer 205 functioning as a back gate, a conductive layer 206a functioning as one of a source and a drain, and a conductive layer 206b functioning as the other of the source and the drain (see FIG. 1B).

Note that the term “gate” and “back gate” can be replaced with each other. For example, in the case where one of the conductive layer 201 and the conductive layer 205 is referred to as a “gate” or a “gate electrode”, the other is referred to as a “back gate” or a “back gate electrode” in some cases. In this specification and the like, one of the conductive layer 201 and the conductive layer 205 is referred to as a “first electrode” and the other is referred to as a “second electrode” in some cases.

The conductive layer 206a functions as one of a source electrode and a drain electrode. The conductive layer 206b functions as the other of the source electrode and the drain electrode. In this specification and the like, one of the conductive layer 206a and the conductive layer 206b is referred to as a “third electrode” and the other is referred to as a “fourth electrode” in some cases.

The conductive layer 201 and the semiconductor layer 203 include a region where they overlap with each other with the dielectric layer 202 therebetween. The conductive layer 205 and the semiconductor layer 203 include a region where they overlap with each other with the dielectric layer 204 therebetween. The region in the semiconductor layer 203 overlaps with the conductive layer 201 functions as a channel formation region 213. The conductive layer 201 and the conductive layer 205 include a region where they overlap with each other with the dielectric layer 202, the semiconductor layer 203, and the dielectric layer 204 therebetween. In other words, the conductive layer 201 and the conductive layer 205 include a region where they overlap with each other with the channel formation region 213 therebetween.

In the semiconductor layer 203, a region where the semiconductor layer 203 and the conductive layer 206a overlap with each other functions as one of a source region and a drain region. In the semiconductor layer 203, a region where the semiconductor layer 203 and the conductive layer 206b overlap with each other functions as the other of the source region and the drain region of the semiconductor layer 203. In this specification and the like, a channel formation region is referred to as a “first region”, one of a source region and a drain region is referred to as a “second region”, and the other of the source region and the drain region is referred to as a “third region” in some cases. Thus, one of the third electrode and the fourth electrode is electrically connected to the second region, and the other is electrically connected to the third region.

As the dielectric layer 202 of the transistor 200 included in the semiconductor device 100, an anti-ferroelectric that is a kind of a material that can have ferroelectricity is used. An anti-ferroelectric exhibits the hysteresis characteristics in the case where an electric field higher than or equal to a certain level or an electric field lower than or equal to a certain level is applied. FIG. 1C is a graph showing an example of hysteresis characteristics of an anti-ferroelectric. In FIG. 1C, the horizontal axis represents the electric field intensity applied to the anti-ferroelectric, and the vertical axis represents the polarization. In FIG. 1C, the minimum polarization and the maximum polarization at the time when the electric field intensity is V1 are denoted by polarization 63a and polarization 64a, respectively. In FIG. 1C, the minimum polarization and the maximum polarization at the time when the electric field intensity is V2 are denoted by polarization 63b and polarization 64b, respectively. Note that the hysteresis characteristics of the material that can have ferroelectricity can be measured with a capacitor using the material that can have ferroelectricity for a dielectric layer.

The transistor 200 of one embodiment of the present invention functions as an FeFET using an anti-ferroelectric that is a kind of a material that can have ferroelectricity for the dielectric layer 202 functioning as a gate insulating layer. The threshold voltage of the FeFET is determined in accordance with the polarization generated in the gate insulating layer. The semiconductor device 100 of one embodiment of the present invention can achieve a memory element capable of retaining multilevel data using the polarization 63a, the polarization 63b, the polarization 64a, and the polarization 64b generated in the anti-ferroelectric.

Here, a material that can have ferroelectricity is described. In this specification and the like, a material that can have ferroelectricity refers to a material that can have hysteresis characteristics in the relationship between the intensity of the electric field applied to the material (electric field intensity) and the polarization magnitude, or a material in which spontaneous polarization occurs even with no external electric field (electric field applied to the material from the outside). Thus, the material that can have ferroelectricity includes a material having one or more of ferroelectricity, anti-ferroelectricity, and ferrielectricity.

In this specification and the like, the material that can have ferroelectricity processed into a layered shape is referred to as a ferroelectric layer in some cases. A device that includes such a ferroelectric layer is sometimes referred to as a ferroelectric device in this specification and the like.

Note that ferroelectricity is presumably exhibited depending on a crystal structure of a crystal included in a ferroelectric layer, which is described later. The crystal structure might change depending on formation conditions or the like of the ferroelectric layer. Thus, in this specification and the like, a material that can be used for forming the ferroelectric layer is referred to as a material that can have ferroelectricity.

In this specification and the like, a material having ferroelectricity or an insulator containing a material having ferroelectricity is referred to as a ferroelectric in some cases. In addition, a material having anti-ferroelectricity or an insulator containing a material having anti-ferroelectricity is referred to as an anti-ferroelectric in some cases. In addition, a material having ferrielectricity or an insulator containing a material having ferrielectricity is referred to as a ferrielectric in some cases.

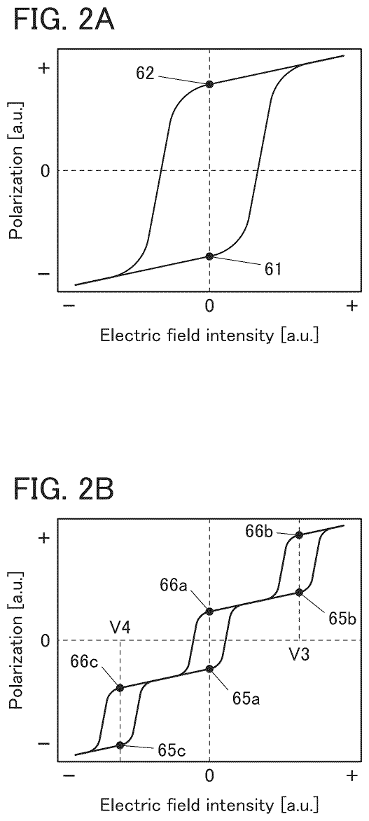

The ferroelectric is an insulator that is polarized even with no external electric field. FIG. 2A is a graph showing an example of hysteresis characteristics of a ferroelectric. In FIG. 2A, the horizontal axis represents the intensity of an electric field applied to the ferroelectric, and the vertical axis represents the polarization of the ferroelectric. Polarization 61 shown in FIG. 2A indicates the minimum polarization at the time when the electric field intensity is 0, and polarization 62 shown in FIG. 2A indicates the maximum polarization at the time when the electric field intensity is 0.

The anti-ferroelectric is an insulator which exhibits a small or no spontaneous polarization with no external electric field; however, in the case where an electric field higher than or equal to a certain level or an electric field lower than or equal to a certain level is applied to the insulator, the insulator exhibits anti-ferroelectricity. Since the polarization direction of adjacent domains is anti-parallel to each other in the anti-ferroelectric, the remanent polarization becomes substantially zero as a whole. Thus, the remanent polarization after the application of the electric field is almost zero; however, the anti-ferroelectric has the same property as the ferroelectric at the time of application of a high electric field. In other words, in the case where the electric field intensity is close to zero, the domain in the anti-ferroelectric mainly has a tetragonal crystal structure, and in the case where the absolute value of the electric field intensity is large, the domain in the anti-ferroelectric mainly has an orthorhombic crystal structure.

FIG. 1C is a graph showing an example of hysteresis characteristics of an anti-ferroelectric. In FIG. 1C, the horizontal axis represents the intensity of an electric field applied to the anti-ferroelectric, and the vertical axis represents the polarization of the anti-ferroelectric. The polarization 63a shown in FIG. 1C is the minimum polarization at the time when the electric field intensity is V1, and the polarization 64a shown in FIG. 1C is the maximum polarization at the time when the electric field intensity is V1. The polarization 63b shown in FIG. 1C is the minimum polarization at the time when the electric field intensity is V2, and the polarization 64b shown in FIG. 1C is the maximum polarization at the time when the electric field intensity is V2. When the electric field intensity is zero, the polarization becomes zero or a value close to zero.

A ferrielectric is an insulator in which first ferroelectricity is exhibited when there is no external electric field or an absolute value of the electric field intensity is small, second ferroelectricity different from the first ferroelectricity is exhibited at the time of application of an electric field higher than or equal to a certain level, and third ferroelectricity different from the first and the second ferroelectricity is exhibited at the time of application of an electric field lower than or equal to a certain level.

FIG. 2B is a graph showing an example of hysteresis characteristics of a ferrielectric. In FIG. 2B, the horizontal axis represents the intensity of an electric field applied to the ferrielectric, and the vertical axis represents the polarization of the ferrielectric. Polarization 65a shown in FIG. 2B indicates the minimum polarization at the time when the electric field intensity is 0, and polarization 66a shown in FIG. 2B indicates the maximum polarization at the time when the electric field intensity is 0. Polarization 65b shown in FIG. 2B indicates the minimum polarization at the time when the electric field intensity is V3, and polarization 66b shown in FIG. 2B indicates the maximum polarization at the time when the electric field intensity is V3. Polarization 65c shown in FIG. 2B indicates the minimum polarization at the time when the electric field intensity is V4, and polarization 66c shown in FIG. 2B indicates the maximum polarization at the time when the electric field intensity is V4.

Note that a material that can have ferroelectricity has a higher dielectric constant than a paraelectric in some cases. The use of a material that can have ferroelectricity for the gate insulating layer of the transistor 200 can reduce the operating voltage of the transistor 200. Thus, the power consumption of the transistor 200 and the semiconductor device including the transistor 200 can be reduced. Alternatively, the operation speed of the transistor 200 can be increased. Alternatively, the area occupied by the transistor 200 can be reduced.

Furthermore, the memory element can be achieved by utilizing the remanent polarization of the ferroelectric. With the use of an anti-ferroelectric or a ferrielectric, a memory element capable of storing multilevel data can be obtained.

Examples of a material that can have ferroelectricity include metal oxides such as hafnium oxide, zirconium oxide, and HfZrOₓ (X is a real number greater than 0).

Examples of the material that can have ferroelectricity also include a metal oxide in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide. Here, the atomic ratio of hafnium to the element J1 can be set as appropriate; the atomic ratio of hafnium to the element J1 is, for example, 1:1 or the neighborhood thereof.

Examples of the material that can have ferroelectricity also include a metal oxide in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide. The atomic ratio of a zirconium atom to the element J2 can be set as appropriate; the atomic ratio of a zirconium atom to the element J2 is, for example, 1:1 or in the neighborhood thereof.

Furthermore, as the material that can have ferroelectricity, piezoelectric ceramics having a perovskite structure, such as PbTiO_{X}; barium strontium titanate (BST), strontium titanate, lead zirconate titanate (PZT), strontium bismuth tantalate (SBT), bismuth ferrite (BFO), or barium titanate can also be used.

As the material that can have ferroelectricity, a mixture or compound containing a plurality of metal oxides selected from the above-listed materials can be used, for example.

Examples of the material that can have ferroelectricity also include a metal nitride containing an element M1, an element M2, and nitrogen. Here, the element M1 is one or more selected from aluminum (Al), gallium (Ga), indium (In), and the like. The element M2 is one or more selected from boron (B), a rare earth element (scandium (Sc), yttrium (Y), and lanthanoid (15 elements from lanthanum (La) to lutetium (Lu)) and actinoid (15 elements from actinium (Ac) to lawrencium (Lr)). It is particularly preferable that the element M2 be one or more selected from boron (B), scandium (Sc), yttrium (Y), lanthanum (La), cerium (Ce), neodymium (Nd), europium (Eu), and the like. Note that the ratio of the total number of atoms of the element M1 and the element M2 to the number of nitrogen atoms is 1:1 or the neighborhood thereof. Note that the neighborhood includes the range of ±30% of an intended ratio between the numbers of atoms. Here, the atomic ratio of the element M1 to the element M2 can be set as appropriate. For example, the number of atoms of the element M1 is preferably greater than the number of atoms of the element M2 and is further preferably 1.5 times or more the number of atoms of the element M2. Note that the atomic ratio of the element M1 to the element M2 preferably falls within the range where the metal nitride can form a solid solution. In the case where two or more of aluminum, gallium, indium, and the like are selected as the element M1, a metal nitride containing the element M1 and nitrogen sometimes has ferroelectricity even when not containing the element M2.

Typical examples of the metal nitride containing the element M1, the element M2, and nitrogen include metal nitrides such as aluminum scandium nitride (Al₁₋ₐScₐN_{b} (a is a real number greater than 0 and less than 0.5, and b is 1 or a value in the neighborhood of 1)), Al—Ga—Sc nitride (Al_{1-c-d}Ga_{c}Sc_{d}N_{b} (c and d are each a positive real number, c+d is greater than 0 and less than 0.5, and b is 1 or a value in the neighborhood of 1)), and Ga—Sc nitride (Ga₁₋ₑScₑN_{b} (e is a real number greater than 0 and less than 1, and b is 1 or a value in the neighborhood of 1)). That is, examples of the material that can have ferroelectricity include a material containing aluminum nitride and/or scandium nitride.

In some cases, it is preferable to use Al—Ga—Sc nitride as the material that can have ferroelectricity, rather than aluminum scandium nitride. The ion radius of gallium is larger than that of aluminum and smaller than that of scandium. It is thus presumable that the crystal structure and lattice constant of aluminum scandium nitride can be adjusted by addition of gallium to the aluminum scandium nitride so that exhibition of ferroelectricity is facilitated. Accordingly, exhibition of ferroelectricity in Al—Ga—Sc nitride is expected. The band gap of gallium nitride is narrower than that of aluminum nitride and wider than that of scandium nitride. Therefore, scandium aluminum nitride has an enhanced insulating property by addition of gallium to aluminum scandium nitride, thereby becoming usable in a later-described ferroelectric device.

Examples of the material that can have ferroelectricity also include a metal nitride containing the element M1, an element M3, and nitrogen. Here, the element M1 is one or more selected from aluminum (Al), gallium (Ga), indium (In), and the like. The element M3 is one or more selected from titanium (Ti), zirconium (Zr), hafnium (Hf), vanadium (V), niobium (Nb), tantalum (Ta), chromium (Cr), molybdenum (Mo), tungsten (W), and the like. In a metal nitride of titanium, zirconium, hafnium, vanadium, niobium, tantalum, or chromium, the valence of the metal element is +3. Thus, in the metal nitride containing the element M1, the element M3, and nitrogen, the valence of the element M3 can also be +3. Therefore, the electrical neutrality of the metal nitride is sometimes maintained when the ratio between the number of nitrogen atoms and the total number of atoms of the element M1 and the element M3 is 1:1 or in the neighborhood thereof.

Note that the metal nitride containing the element M1, the element M3, and nitrogen may contain an element M4. Here, the element M4 is an element that can maintain the electrical neutrality of the metal nitride. The element M4 is, for example, an element that easily has a valence of +1 or an element that easily has a valence of +2. The element M4 is, specifically, one or more selected from sodium (Na), potassium (K), rubidium (Ru), cesium (Cs), magnesium (Mg), calcium (Ca), strontium (Sr), zinc (Zn), cadmium (Cd), and the like. Titanium, zirconium, hafnium, vanadium, niobium, tantalum, chromium, molybdenum, or tungsten, which is given as an example of the element M3, can have a valence greater than or equal to +4. It is thus presumable that the electrical neutrality of the metal nitride is maintained when the metal nitride contains the element M4 that can maintain the electrical neutrality of the metal nitride. Note that the ratio between the number of atoms of the element M3 and the number of atoms of the element M4 can be appropriately set in accordance with the kind of the element selected as the element M3 or the element M4. For example, in the case where the element M4 is an element that easily has a valence of +2 (e.g., Mg. Ca, Sr, Zn, or Cd) and the element M3 is an element that can have a valence of +4 (e.g., Ti, Zr, or Hf), the ratio between the number of atoms of the element M4 and the number of atoms of the element M3 is preferably 1:1 or in the neighborhood thereof. In the case where the element M4 is an element that easily has a valence of +2 and the element M3 is an element that can have a valence of +5 (e.g., V. Nb, or Ta), alternatively, the ratio between the number of atoms of the element M4 and the number of atoms of the element M3 is preferably 2:1 or in the neighborhood thereof. In the case where the element M4 is an element that easily has a valence of +1 (e.g., Na, K, Ru, or Cs) and the element M3 is an element that can have a valence of +5, further alternatively, the ratio between the number of atoms of the element M4 and the number of atoms of the element M3 is preferably 1:1 or in the neighborhood thereof. Note that the preferable atomic ratio of the element M3 to the element M4 is not limited to the above. The crystal structure of the metal nitride can be changed depending on the atomic ratio between the metal and nitrogen. Thus, the atomic ratio between the element M3 and the element M4 is preferably set as appropriate so that ferroelectricity is exhibited. The atomic ratio of the element M1 to the element M3 and the element M4 can be set as appropriate. For example, the number of atoms of the element M1 is preferably greater than the total number of atoms of the element M3 and the element M4.

The metal nitride containing the element M1, the element M2, and nitrogen may contain the element M3 or the element M4. In that case, the ratio of the number of atoms of the element M3 or the element M4 to the total number of atoms of the element M1 and the element M2 is preferably less than or equal to 0.05, further preferably less than or equal to 0.02. That makes it possible to reduce the amount of defects formed to maintain the electrical neutrality of the metal nitride. Reducing the amount of defects enables the crystallinity of the metal nitride to be improved and ferroelectricity to be easily exhibited.

The metal nitride containing the element M1, the element M3, and nitrogen may contain the element M2. In that case, there is no particular limitation on the ratio of the total number of atoms of the element M1 and the element M3 to the number of atoms of the element M2. This is because the electrical neutrality of the metal nitride is maintained even when the metal nitride contains the element M2.

The metal nitride containing the element M1, the element M3, the element M4, and nitrogen may contain the element M2. In that case, there is no particular limitation on the ratio of the total number of atoms of the element M1, the element M3, and the element M4 to the number of atoms of the element M2. This is because the electrical neutrality of the metal nitride is maintained even when the metal nitride contains the element M2.

As the material that can have ferroelectricity, a mixture or compound containing a plurality of metal nitrides selected from the above-listed materials can be used, for example.

Among the materials that can have ferroelectricity, a material containing hafnium oxide or hafnium oxide and zirconium oxide is preferable because the material can have ferroelectricity even when being processed into a thin film of several nanometers. When a ferroelectric layer that can be thinned is used for a gate insulating layer or the like, a semiconductor device including a miniaturized semiconductor element such as a transistor can be manufactured.

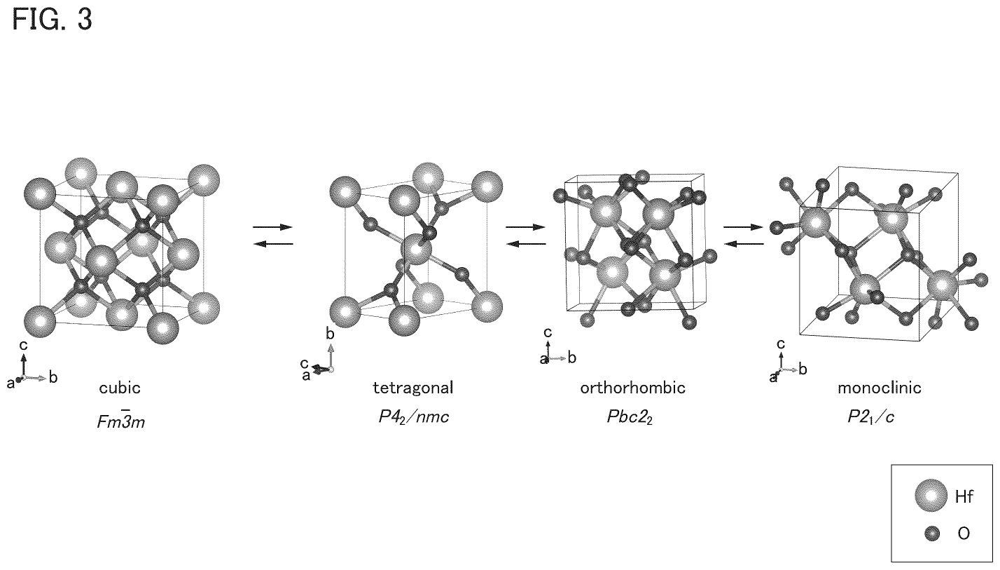

Here, crystal structures of hafnium oxide, which is a material that can be used as a gate insulating layer, or the like are described with reference to FIG. 3. FIG. 3 is a model diagram illustrating crystal structures of hafnium oxide (HfO₂ in this embodiment). Hafnium oxide is known to take on various crystal structures and, for example, can take on crystal structures illustrated in FIG. 3 such as cubic (space group: Fm-3m), tetragonal (space group: P4₂/nmc), orthorhombic (space group: Pbc2₂), and monoclinic (space group: P2₁/c) crystal structures. As illustrated in FIG. 3, phase transition can occur between the above-described crystal structures. For example, the crystal structure of hafnium oxide can be changed from a crystal structure mainly based on a monoclinic system to a crystal structure mainly based on an orthorhombic system when the hafnium oxide is doped with zirconium to form a composite material.

In the case where hafnium oxide and zirconium oxide are alternately deposited by an atomic layer deposition (ALD) method or the like so as to achieve a composition ratio of hafnium oxide to zirconium oxide that is approximately 1:1 as the above-described composite material, the composite material has an orthorhombic crystal structure. Alternatively, the composite material has an amorphous structure. Then, the application of heat treatment or the like to the composite material can change the crystal structure from the amorphous structure to an orthorhombic crystal structure. In some cases, the orthorhombic crystal structure can change to a monoclinic crystal structure. To make the above-described composite material have ferroelectricity, an orthorhombic crystal structure is preferred to a monoclinic crystal structure.

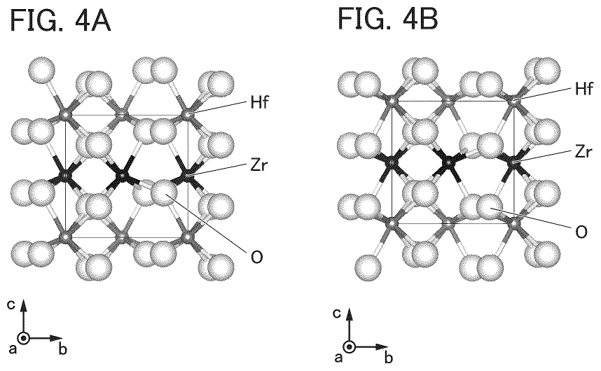

Here, a model of an orthorhombic crystal structure of HfZrOₓ is described with reference to FIG. 4A and FIG. 4B.

FIG. 4A and FIG. 4B are model diagrams of the crystal structure of HfZrOₓ, which is here Hf_{0.5}Zr_{0.5}O₂. In FIG. 4A and FIG. 4B, the directions of the a-axis, the b-axis, and the c-axis are also indicated. FIG. 4A and FIG. 4B are models in which the arrangement of atoms is optimized by first-principles calculation on the orthorhombic structure (Pca2₁) of HfO₂.

In FIG. 4A and FIG. 4B, hafnium and zirconium are bonded to each other with oxygen positioned therebetween. This can be formed by alternately depositing hafnium and zirconium by an ALD method.

Note that HfZrOₓ having an orthorhombic structure can take either the atomic arrangement illustrated in FIG. 4A or the atomic arrangement illustrated in FIG. 4B. Accordingly, when part of oxygen atoms in HfZrOₓ is displaced by the electric field applied from the outside, the polarization is generated inside. Here, part of oxygen atoms is displaced in the c-axis direction, and the polarization is also generated in the c-axis direction. A change in the direction or intensity of the electric field allows part of oxygen atoms in HfZrOₓ to be moved, resulting in a change of signs of the polarization generated inside.

For example, at the minimum polarization (the polarization 61 shown in FIG. 2A), atoms in HfZrOₓ are located as illustrated in FIG. 4A. At the maximum polarization (the polarization 62 shown in FIG. 2A), atoms in HfZrOₓ are located as illustrated in FIG. 4B.

The gate insulating layer or the like has a single crystal structure in at least part of its crystal structure. The gate insulating layer or the like have any one or more of crystal structures selected from cubic, tetragonal, orthorhombic, and monoclinic crystal structures. The gate insulating layer or the like especially preferably has an orthorhombic crystal structure to exhibit ferroelectricity. Alternatively, the gate insulating layer or the like may have an amorphous structure. Alternatively, the gate insulating layer or the like may have a composite structure that includes an amorphous structure and a crystal structure.

For example, the crystal structure of hafnium oxide can be sometimes changed from a crystal structure mainly based on a monoclinic system to a crystal structure mainly based on a tetragonal system when the hafnium oxide is doped with zirconium to form a composite material. In that case, the composite material has anti-ferroelectricity in some cases. In other words, a tetragonal crystal structure is preferred to a monoclinic crystal structure to make the above-described composite material have ferroelectricity.

For example, at the minimum polarization when the electric field intensity is V2 (the polarization 63b shown in FIG. 1C), atoms in HfZrOₓ are located as illustrated in FIG. 4A. At the maximum polarization when the electric field intensity is V1 (the polarization 64a shown in FIG. 1C), atoms in HfZrOₓ are located as illustrated in FIG. 4B. Note that atoms in HfZrOₓ are mainly arranged in a tetragonal system (space group: P4₂/nmc) illustrated in FIG. 3 at the polarization when the electric field intensity is 0, at the minimum polarization when the electric field intensity is V1 (the polarization 63a shown in FIG. 1C), and at the maximum polarization when the electric field intensity is V2 (the polarization 64b shown in FIG. 1C).

Note that in the above composite material, the content of zirconium to hafnium is preferably large. For example, as the above-described composite material, a composite material having a composition of Hf:Zr=1:2 [atomic ratio] or in the neighborhood thereof, or a composite material having a composition of Hf:Zr=1:3 [atomic ratio] or in the neighborhood thereof is used. Note that a composition in the neighborhood includes the range of ±30% of an intended atomic ratio. When the content of zirconium to hafnium is increased, anti-ferroelectricity is likely to be exhibited in the composite material.

### <<Hysteresis Characteristics of Anti-Ferroelectric>>

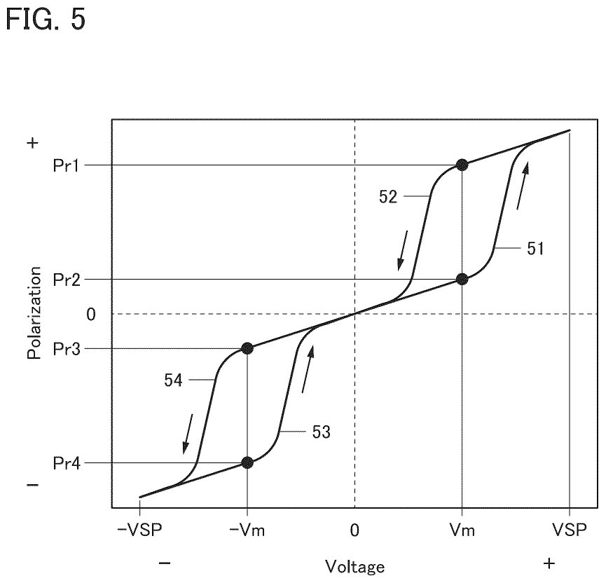

Here, hysteresis characteristics of an anti-ferroelectric are described in detail. FIG. 5 is a graph showing an example of hysteresis characteristics. The hysteresis characteristics can be measured using a capacitor including an anti-ferroelectric as a dielectric layer. In FIG. 5, the horizontal axis represents voltage (electric field) applied to the anti-ferroelectric. This voltage is a potential difference between one electrode and the other electrode of the capacitor including the anti-ferroelectric as the dielectric layer. The electric field intensity can be obtained by dividing the potential difference by the thickness of the dielectric layer.

In FIG. 5, the vertical axis represents the polarization in the dielectric layer. Positive polarization indicates that positive charge in the dielectric layer is biased toward one electrode side of the capacitor and negative charge is biased toward the other electrode side of the capacitor. By contrast, negative polarization indicates that negative charge in the dielectric layer is biased toward one electrode side of the capacitor and positive charge is biased toward the other electrode side of the capacitor.

The polarization represented by the vertical axis of the graph in FIG. 5 may be positive when negative charge is biased toward one electrode side of the capacitor and positive charge is biased toward the other electrode side of the capacitor, and may be negative when positive charge is biased toward one electrode side of the capacitor and negative charge is biased toward the other electrode side of the capacitor.

In the case of applying a positive voltage higher than or equal to a certain level or a negative voltage lower than or equal to a certain level, an anti-ferroelectric exhibits hysteresis characteristics. The change in the polarization at the time when a positive voltage is applied to the anti-ferroelectric can be expressed by a curve 51 and a curve 52. The curve 51 and the curve 52 intersect with each other when the voltage is 0 V and the voltage is a saturated polarization voltage VSP.

When the voltage applied to the anti-ferroelectric is increased in the positive direction after 0 V or a negative voltage is applied to the anti-ferroelectric, the polarization of the ferroelectric layer increases in the positive direction along the curve 51. When the voltage applied to the ferroelectric layer is reduced in the direction toward 0 V after the saturated polarization voltage VSP or a higher voltage is applied to the ferroelectric layer, the polarization of the anti-ferroelectric reduces along the curve 52. When the voltage applied to the ferroelectric layer becomes 0 V, the polarization also becomes 0. At the time when a voltage Vm is applied, the polarization on the curve 52 is referred to as “polarization Pr1” and the polarization on the curve 51 is referred to as “polarization Pr2”.

The change in the polarization at the time when a negative voltage is applied to the anti-ferroelectric can be expressed by a curve 53 and a curve 54. The curve 53 and the curve 54 intersect with each other when the voltage is 0 V and the voltage is a saturated polarization voltage −VSP.

When the voltage applied to the anti-ferroelectric is increased in the negative direction after 0 V or a positive voltage is applied to the anti-ferroelectric, the polarization of the ferroelectric layer increases in the negative direction along the curve 54. When the voltage applied to the anti-ferroelectric is reduced toward 0 V after −VSP or a lower voltage is applied to the ferroelectric layer, the polarization of the anti-ferroelectric shifts toward 0 along the curve 53. When the voltage applied to the ferroelectric layer becomes 0 V, the polarization also becomes 0. At the time when a voltage −Vm is applied, the polarization on the curve 54 is referred to as “polarization Pr3” and the polarization on the curve 53 is referred to as “polarization Pr4”.

Note that in some cases, the saturated polarization voltage VSP is referred to as a “positive saturation polarization voltage” or a “first saturation polarization voltage”, and a saturated polarization voltage −VSP is referred to as a “negative saturation polarization voltage” or a “second saturation polarization voltage”. The absolute value of the first saturation polarization voltage may be the same as or different from the absolute value of the second saturation polarization voltage.

### <<Operation Example of Memory Cell>>

Next, an operation of the semiconductor device 100 is described. The semiconductor device 100 of one embodiment of the present invention functions as a memory cell capable of retaining multilevel data. First, the relation between the polarization of the anti-ferroelectric and Id-Vg characteristics of the transistor 200 is described.

### <Relation Between Polarization of Anti-Ferroelectric and Id-Vg Characteristics>

The relation between the polarization of the anti-ferroelectric used for the dielectric layer 202 of the transistor 200 and the threshold voltage of the transistor 200 is described with reference to drawings.

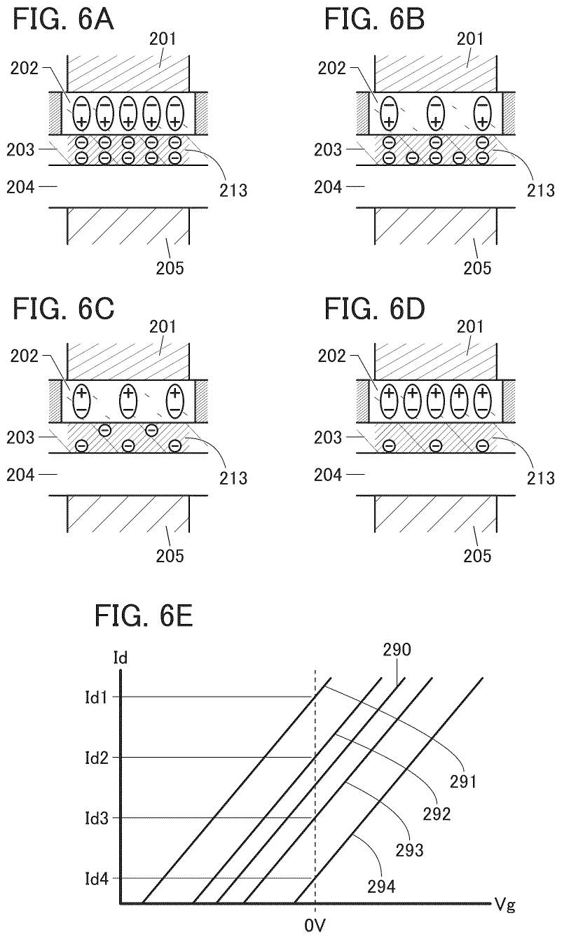

FIG. 6A to FIG. 6D are enlarged schematic cross-sectional views of the vicinity of the dielectric layer 202 and the channel formation region 213 in the transistor 200. FIG. 6A to FIG. 6D schematically illustrate the polarization of the dielectric layer 202, which is an anti-ferroelectric, and the carrier concentration in the channel formation region 213.

FIG. 6E is a diagram showing Id-Vg characteristics of the transistor 200 at the time when the voltage between the source and the drain (also referred to as a “drain voltage” or “Vd”) is constant. In FIG. 6E, the horizontal axis represents voltage between the source and the gate (also referred to as a “gate voltage” or “Vg”), and the vertical axis represents current flowing between the source and the drain (also referred to as a “drain current” or “Id”).

In FIG. 6E, characteristics 290 show Id-Vg characteristics of the transistor 200 at the time when polarization is not generated in the dielectric layer 202. The transistor 200 is a normally-on transistor in which a large amount of Id flows when Vg is 0 V.

In FIG. 6E, characteristics 291 show Id-Vg characteristics at the time when the polarization of the dielectric layer 202 is the polarization Pr1. FIG. 6A is a schematic view illustrating the polarization and the carrier concentration of the characteristics 291 at the time when Vg is 0 V.

Since the polarization Pr1 is large positive polarization, the carrier concentration of the channel formation region 213 of the semiconductor layer 203 is increased.

Thus, Id-Vg characteristics of the characteristics 290 shift largely in the negative direction to be the characteristics 291. In other words, the threshold voltage of the transistor 200 shifts largely in the negative direction. In FIG. 6E, Id at the time when Vg is 0 V in the characteristics 291 is denoted by current Id1.

In FIG. 6E, characteristics 292 show Id-Vg characteristics at the time when the polarization of the dielectric layer 202 is the polarization Pr2. FIG. 6B is a schematic view illustrating the polarization and the carrier concentration at the time when Vg is 0 V in the characteristics 292.

Since the polarization Pr2 is positive polarization smaller than the polarization Pr1, an increase in the carrier concentration of the channel formation region 213 in the semiconductor layer 203 is less than that at the polarization Pr1. Thus, Id-Vg characteristics of the characteristics 290 shift in the negative direction to be the characteristics 292, though its influence is less than that in the case where the polarization of the dielectric layer 202 is the polarization Pr1. That is, the threshold voltage of the transistor 200 shifts in the negative direction, though the shift amount is smaller than that with the polarization Pr1. In FIG. 6E, Id at the time when Vg is 0 V in the characteristics 292 is denoted by current Id2.

In FIG. 6E, characteristics 293 show Id-Vg characteristics at the time when the polarization of the dielectric layer 202 is the polarization Pr3. FIG. 6C is a schematic view illustrating the polarization and the carrier concentration when Vg is 0 V in the characteristics 293.

Since the polarization Pr3 is negative polarization, the carrier concentration of the channel formation region 213 in the semiconductor layer 203 decreases. Thus, Id-Vg characteristics of the characteristics 290 shift in the positive direction to be the characteristics 293. In other words, the threshold voltage of the transistor 200 shifts in the positive direction. In FIG. 6E, Id at the when Vg is 0 V in the characteristics 293 is denoted by current Id3.

In FIG. 6E, characteristics 294 show Id-Vg characteristics at the time when the polarization of the dielectric layer 202 is the polarization Pr4. FIG. 6D is a schematic view illustrating the polarization and the carrier concentration at the time when Vg is 0 V in the characteristics 294.

Since the polarization Pr4 is negative polarization larger than the polarization Pr3, the carrier concentration of the channel formation region 213 in the semiconductor layer 203 is significantly reduced. Thus, Id-Vg characteristics of the characteristics 290 shift largely in the positive direction to be the characteristics 294. In other words, the threshold voltage of the transistor 200 shifts largely in the positive direction. In FIG. 6E, Id at the time when Vg is 0 V in the characteristics 294 is denoted by current Id4.

As illustrated in FIG. 6A to FIG. 6E, Id-Vg characteristics of the transistor 200 can be changed in accordance with the polarization of the dielectric layer 202. In other words, by controlling the polarization of the dielectric layer 202, the threshold voltage of the transistor 200 can be controlled. In addition, with the use of an anti-ferroelectric for the dielectric layer 202, one transistor 200 can control the achievement of four threshold voltages. Thus, the semiconductor device 100 including the transistor 200 can function as a memory cell that can retain four-level data.

For example, in the case where four level data of data “0” to data “3” are written in the semiconductor device 100 functioning as a memory cell, the polarization of the dielectric layer 202 is the polarization Pr1 when the data “0” is written, the polarization of the dielectric layer 202 is the polarization Pr2 when data “1” is written, the polarization of the dielectric layer 202 is the polarization Pr3 when data “2” is written, and the polarization of the dielectric layer 202 is the polarization Pr4 when the data “3” is written.

In addition, depending on the polarization of the dielectric layer 202, Id at the time when Vg is 0 V corresponds to any of the current Id1, the current Id2, the current Id3, and the current Id4. Thus, by measuring Id at the time when Vg is 0 V, data written to the memory cell can be read.

With the use of the characteristics 290 that are Id-Vg characteristics at the time when polarization is not generated in the dielectric layer 202 in addition to the characteristics 291 to the characteristics 294, a memory cell capable of retaining five-level data can be achieved.

Id needs to flow in the transistor 200 when Vg is 0 V in the case where the polarization of the dielectric layer 202 is any of the polarization Pr1 to the polarization Pr4. The transistor 200 is preferably a normally-on transistor in which Id flows when Vg is 0 V in the case where the polarization of the dielectric layer 202 is any of the polarization Pr1 to the polarization Pr4.

### <Erasing Operation>

Before data is written to the semiconductor device 100 functioning as a memory cell, data needs to be erased. That is, the polarization of the dielectric layer 202 is set to 0.

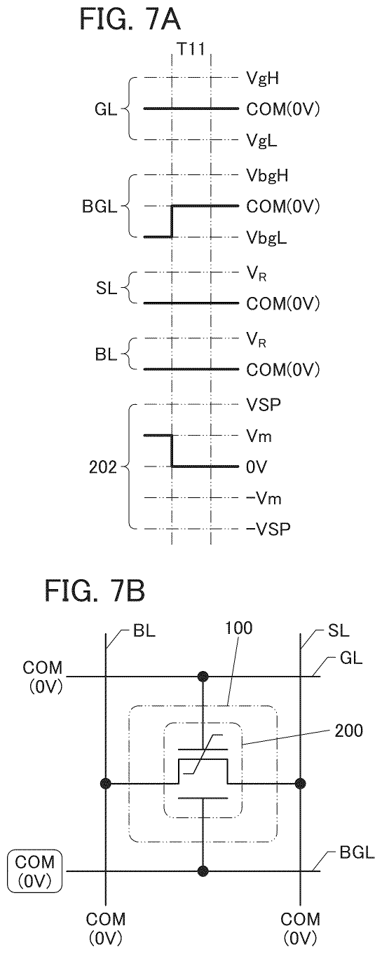

FIG. 7A is a timing chart for illustrating an erasing operation. FIG. 7B is a circuit diagram illustrating a state of the semiconductor device 100 in Period T11. Note that in a circuit diagram and the like, for easy understanding of a potential of a wiring or the like, a symbol showing the potential of the wiring is sometimes illustrated adjacent to the wiring or the like. Furthermore, an enclosed character is sometimes written near a wiring or the like whose potential has changed.

In Period T11, a common potential COM (0 V) is supplied to the wiring GL and the wiring BGL, so that the gate and the back gate of the transistor 200 are set to the same potential. The wiring BL and the wiring SL are also preferably set to the common potential COM. As illustrated in FIG. 5, no potential difference between the gate and the back gate (a potential difference of 0) eliminates the polarization of the dielectric layer 202 (the polarization becomes 0). Note that the horizontal axis in FIG. 5 corresponds to the potential difference between the gate and the back gate at the time when the back gate is used as a reference, that is, corresponds to a potential difference between the wiring GL and the wiring BGL.

### <Writing Operation 1>

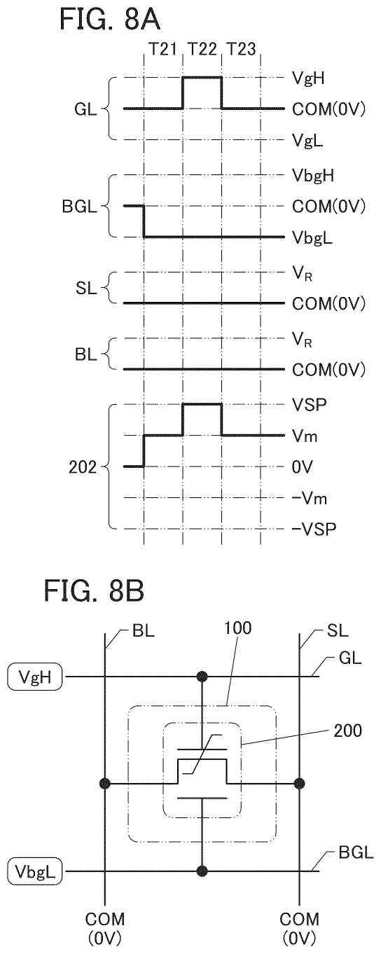

Next, operation of writing the data “0” to the semiconductor device 100 functioning as a memory cell will be described. FIG. 8A is a timing chart for illustrating the writing operation. FIG. 8B is a circuit diagram illustrating a state of the semiconductor device 100 in Period T22.

After the erasing operation is performed, the potential of the wiring BGL is set to a potential VbgL in Period T21. Note that the potential VbgL is a potential lower than the common potential COM. The wiring GL remains the common potential COM. Then, the voltage Vm is applied to the dielectric layer 202 in Period T21. The voltage Vm is a potential difference between the common potential COM and the potential VbgL at the time when the wiring BGL is used as a reference. Note that the voltage Vm can be expressed as the voltage Vm=the potential COM−the potential VbgL.

In Period T21, the polarization of the dielectric layer 202 changes along the curve 51 to be the polarization Pr2 (see FIG. 5). That is, the data “1” is written to the semiconductor device 100.

Next, in Period T22, while the potential of the wiring BGL remains the potential VbgL, the potential of the wiring GL is set to a potential VgH. The potential VgH is a potential satisfying the potential VgH>=the saturated polarization voltage VSP+the potential VbgL. That is, the potential VgH is a potential applying a voltage higher than or equal to the saturated polarization voltage VSP to the dielectric layer 202.

Next, in Period T23, the potential of the wiring GL is set to the common potential COM. In Period T23, the polarization of the dielectric layer 202 changes along the curve 52 to be the polarization Pr1. That is, the data “0” is written to the semiconductor device 100. In Period T23, the potential difference between the wiring GL and the wiring BGL becomes the voltage Vm. Thus, the voltage Vm is applied to the dielectric layer 202.

After Period T23, the voltage Vm is kept applied to the dielectric layer 202, whereby the polarization Pr1 is maintained. That is, the data “O” is retained in the semiconductor device 100. Note that the data “1” is written to the semiconductor device 100 in Period T21 in the step of writing the data “0”. After Period T21, the voltage Vm is kept applied to the dielectric layer 202, whereby the polarization Pr2 is maintained. That is, the data “1” is retained in the semiconductor device 100.

### <Writing Operation 2>

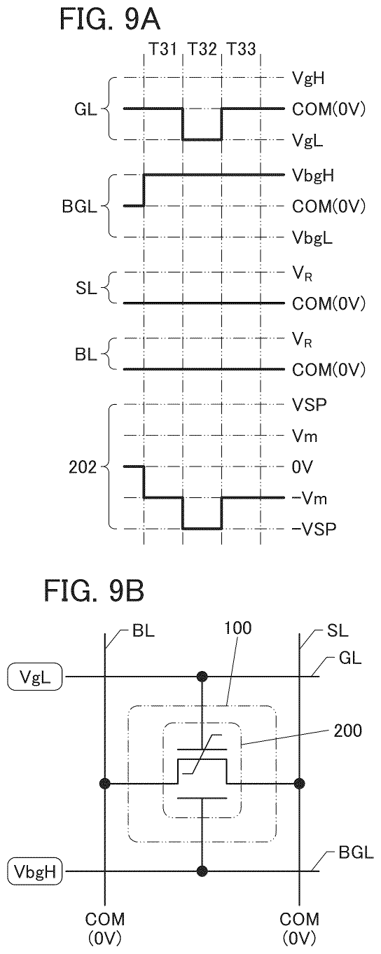

Next, operation of writing the data “3” to the semiconductor device 100 functioning as a memory cell will be described. FIG. 9A is a timing chart for illustrating the writing operation. FIG. 9B is a circuit diagram illustrating a state of the semiconductor device 100 in Period T32.

After the erasing operation is performed, the potential of the wiring BGL is set to a potential VbgH in Period T31. Note that the potential VbgH is a potential higher than the common potential COM. The wiring GL remains the common potential COM. Then, a voltage −Vm is applied to the dielectric layer 202 in Period T31. The voltage −Vm is a potential difference between the common potential COM and the potential VbgL at the time when the wiring BGL is used as a reference. The voltage −Vm can be expressed as the voltage −Vm=the common potential COM−the potential VbgH.

In Period T31, the polarization of the dielectric layer 202 changes along the curve 54 to be the polarization Pr3 (see FIG. 5). That is, the data “2” is written to the semiconductor device 100.

Next, in Period T32, while the potential of the wiring BGL remains the potential VbgH, the potential of the wiring GL is set to a potential VgL. The potential VgL is a potential satisfying the potential VgL<=the saturated polarization voltage −VSP+the potential VbgH. That is, the potential VgL is a potential for applying a negative voltage whose absolute value is larger than or equal to the saturated polarization voltage VSP to the dielectric layer 202.

Next, in Period T33, the potential of the wiring GL is set to the common potential COM. In Period T33, the polarization of the dielectric layer 202 changes along the curve 53 to be the polarization Pr4. That is, the data “3” is written to the semiconductor device 100. In Period T33, the potential difference between the wiring GL and the wiring BGL becomes a voltage −Vm. Thus, the voltage −Vm is applied to the dielectric layer 202.

After Period T33, the voltage −Vm is kept applied to the dielectric layer 202, whereby the polarization Pr4 is maintained. That is, the data “3” is retained in the semiconductor device 100. Note that the data “2” is written to the semiconductor device 100 in Period T31 in the step of writing the data “3”. After Period T31, the voltage −Vm is kept applied to the dielectric layer 202, whereby the polarization Pr3 is maintained. That is, the data “2” is retained in the semiconductor device 100.

Data can be written to the semiconductor device 100 in such a manner.

### <Reading Operation>

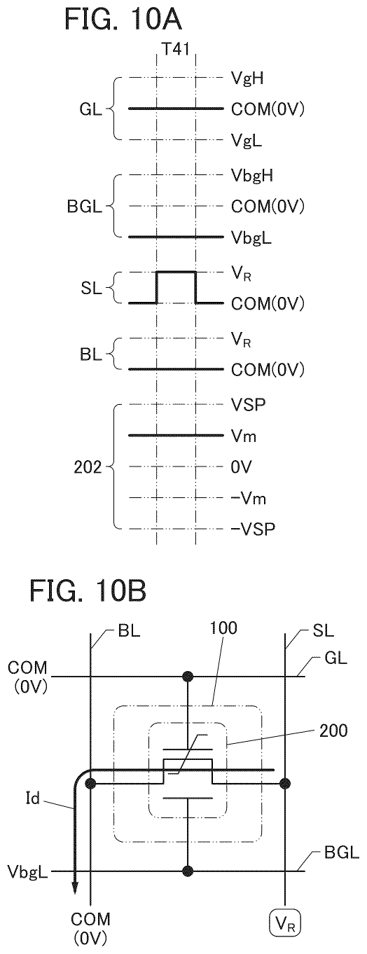

Next, operation of reading data retained in the semiconductor device 100 functioning as a memory cell is described. FIG. 10A is a timing chart for illustrating the reading operation. FIG. 10B is a circuit diagram illustrating a state of the semiconductor device 100 in Period T41.

Data retained in the semiconductor device 100 can be read by generating a potential difference between the wiring SL and the wiring BL while the potentials of the wiring GL and the wiring BGL are maintained, and detecting current flowing through the wiring BL or current flowing through the wiring SL.

Specifically, in Period T41, a potential VR is supplied to the wiring SL. The potential VR is such a potential that the potential difference between the wiring SL and the wiring BL becomes lower than or equal to the voltage Vm, preferably lower than or equal to ½ of the voltage Vm. A too large potential difference between the wiring SL and the wiring BL sometimes affects the polarization of the dielectric layer 202. Therefore, the potential difference between the wiring SL and the wiring BL is preferably small.

For example, when the voltage Vm is applied to the wiring SL and the value of Id at this time is the same as the current Id1, it can be determined that the semiconductor device 100 retains the data “0”. For example, when the current value of Id is the same as that of the current Id4, it can be determined that the semiconductor device 100 retains the data “3”.

In order to achieve stable reading operation, it is preferable that the current difference between the current Id1 and the current Id2, the current difference between the current Id2 and the current Id3, and the current difference between the current Id3 and the current Id4 be equal to each other. That is, the current values of the current Id1, the current Id2, the current Id3, and the current Id4 preferably have regular intervals. Thus, the polarization Pr1 to the polarization Pr4 of the dielectric layer 202 preferably have regular intervals.

The value of the polarization Pr1 to the polarization Pr4 can be controlled by the voltage Vm and the voltage −Vm. As described above, the voltage Vm is the potential difference between the wiring GL and the wiring BGL. In the case where data is read from the semiconductor device 100, the voltage Vm can be controlled by the value of the potential VbgL supplied to the wiring BGL because the wiring GL is the common potential COM (0 V). Similarly, the voltage −Vm can be controlled by the value of the potential VbgH supplied to the wiring BGL. By controlling the potential supplied to the wiring BGL, the values of the polarization Pr1 to the polarization Pr4 and the current Id1 to the current Id4 can be controlled.

According to one embodiment of the present invention, a semiconductor device capable of storing multilevel data can be achieved. According to one embodiment of the present invention, a semiconductor device with high memory capacity can be achieved.

This embodiment can be combined as appropriate with any of the other embodiments and the like described in this specification.

### Embodiment 2

A structure example of a memory device 300 including the semiconductor device 100 functioning as a memory cell is described.

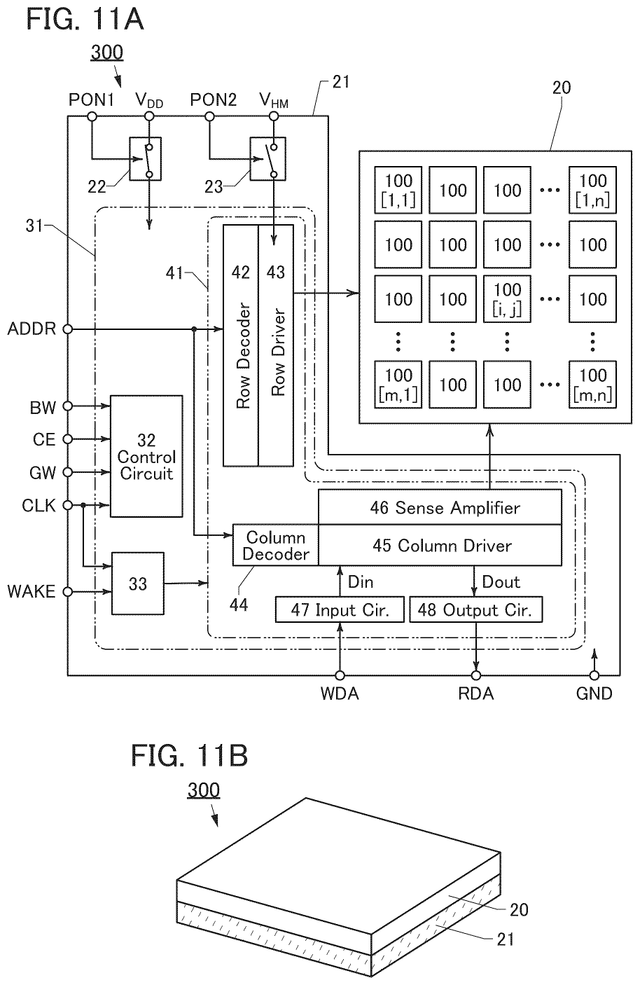

FIG. 11A is a block diagram illustrating a structure example of the memory device 300. The memory device 300 includes a driver circuit 21 and a memory array 20. The memory array 20 includes a plurality of semiconductor devices 100. FIG. 11A illustrates an example in which the memory array 20 includes the plurality of semiconductor devices 100 arranged in a matrix of m rows and n columns (m is an integer of greater than or equal to 2 and n is an integer of greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 11A, the semiconductor device 100 in the first row and the first column is denoted by a semiconductor device 100[1,1]; the semiconductor device 100 in the first row and the n-th column is denoted by a semiconductor device 100[1,n]; the semiconductor device 100 in the m-th row and the first column is denoted by a semiconductor device 100[m, 1]; and the semiconductor device 100 in the m-th row and the n-th column is denoted by a semiconductor device 100[m,n]. Furthermore, the semiconductor device 100 in the i-th row and the j-th column (i is an integer greater than or equal to 1 and less than or equal to m and j is an integer greater than or equal to 1 and less than or equal to n) is denoted by a semiconductor device 100[i,j].

The memory array 20 includes m wirings GL and m wirings BGL extending in the row direction and n wirings SL and n wirings BL extending in the column direction (not illustrated). In this embodiment and the like, an i-th (i-th row) wiring GL is referred to as a wiring GL[i] in some cases. An i-th (i-th row) wiring BGL is referred to as a wiring BGL[i] in some cases. A j-th (j-th column) wiring SL is referred to as a wiring SL[j] in some cases. A j-th (j-th column) wiring BL is referred to as a wiring BL[j] in some cases.

The plurality of semiconductor devices 100 provided in the j-th column are electrically connected to the wiring BL[j] and the wiring SL[j] (not illustrated). The plurality of semiconductor devices 100 provided in the i-th row are electrically connected to the wiring GL[i] and the wiring BGL[i] (not illustrated).

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the semiconductor devices 100. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring GL specified by the row decoder 42. The column driver 45 has a function of writing data to the semiconductor devices 100, a function of reading data from the semiconductor devices 100, a function of retaining the read data, and the like.

The input circuit 47 has a function of retaining the signal WDA. Data retained by the input circuit 47 is output to the column driver 45. Data output from the input circuit 47 is data (Din) to be written to the semiconductor devices 100. Data (Dout) read from the semiconductor devices 100 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of V_{DD} to the peripheral circuit 31. The PSW 23 has a function of controlling supply of V_{HM} to the row driver 43. Here, in the memory device 300, a high power supply potential is V_{DD} and a low power supply voltage is GND (a ground potential). In addition, V_{HM} is a high power supply potential used to set a word line at a high level and is higher than V_{DD}. The on/off of the PSW 22 is controlled by the signal PON1, and the on/off of the PSW 23 is controlled by the signal PON2. The number of power domains to which V_{DD} is supplied is one in the peripheral circuit 31 in FIG. 11A but can be more than one. In this case, a power switch is provided for each power domain.

The driver circuit 21 and the memory array 20 may be provided on the same plane. As illustrated in FIG. 11B, the driver circuit 21 and the memory array 20 may be provided to overlap with each other. When the driver circuit 21 and the memory array 20 are provided to overlap with each other, the signal transmission distance can be shortened. Accordingly, resistance and parasitic capacitance between the driver circuit 21 and the memory array 20 are reduced, so that power consumption and signal delays can be reduced. In addition, the memory device 300 can be downsized.

As described above, the semiconductor device 100 of one embodiment of the present invention functions as a memory cell capable of retaining multilevel data. The use of the semiconductor device 100 as a memory cell of the memory device 300 enables a memory device with high memory capacity.

This embodiment can be combined as appropriate with any of the other embodiments and the like described in this specification.

### Embodiment 3

In this embodiment, a structure example of a transistor that can be used as the transistor 200 included in the semiconductor device 100 will be described.

Note that as the transistor 200 of one embodiment of the present invention, a transistor with any of a variety of structures can be used. For example, as the semiconductor layer 203 (see FIG. 1B) in which the channel of the transistor 200 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, oxide semiconductor, or nitride semiconductor may be used.

Especially, a transistor including an oxide semiconductor, which is a kind of a metal oxide, in a semiconductor layer where a channel is formed (also referred to as an “OS transistor”) is preferably used as the transistor 200. An oxide semiconductor has a band gap higher than or equal to 2 eV, and thus has an extremely low off-state current. Thus, the power consumption of the semiconductor device 100 can be reduced. Thus, power consumption of a semiconductor device including the semiconductor device 100 can be reduced.

For example, the transistor using polycrystalline silicon has variation in the threshold voltage caused by a crystal grain boundary, whereas the OS transistor has little influence by a crystal grain boundary and small variation in the threshold voltage. Accordingly, when the OS transistor is used as the transistor 200, malfunction of a memory cell caused by variation in the threshold voltage can be inhibited.

The OS transistor operates stably even in a high-temperature environment and has small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. The semiconductor device 100 including the OS transistor can operate stably and have high reliability even in a high-temperature environment. Furthermore, the OS transistor has high withstand voltage between its source and drain. By using OS transistors as transistors included in a memory cell, the operation of the memory cell is stabilized even in a high-temperature environment, whereby highly reliable memory cell can be achieved. The use of an OS transistor as the transistor 200 can increase the reliability of a memory device including the semiconductor device 100.

Since silicon is easily oxidized, when silicon is used for the semiconductor layer 203, oxygen contained in the dielectric layer 202 that can have ferroelectricity reacts with silicon in the semiconductor layer 203 and defects are likely to be generated at the interface between the dielectric layer 202 and the semiconductor layer 203 and the vicinity thereof. Thus, the electrical characteristics and reliability of a transistor 400 used as an FeFET are likely to deteriorate.

Since an oxide semiconductor is an oxide, with the use of an oxide semiconductor for the semiconductor layer 203, defects are less likely to occur at the interface between the semiconductor layer 203 and the dielectric layer 202 and in the vicinity of the interface. Thus, the transistor 200 used as the FeFET can have stable electrical characteristics and higher reliability.

Note that a memory cell including an OS transistor is sometimes referred to as an “OS memory”. A memory device including the memory cell can also be referred to as an “OS memory”.

### <Structure Example of OS Transistor>

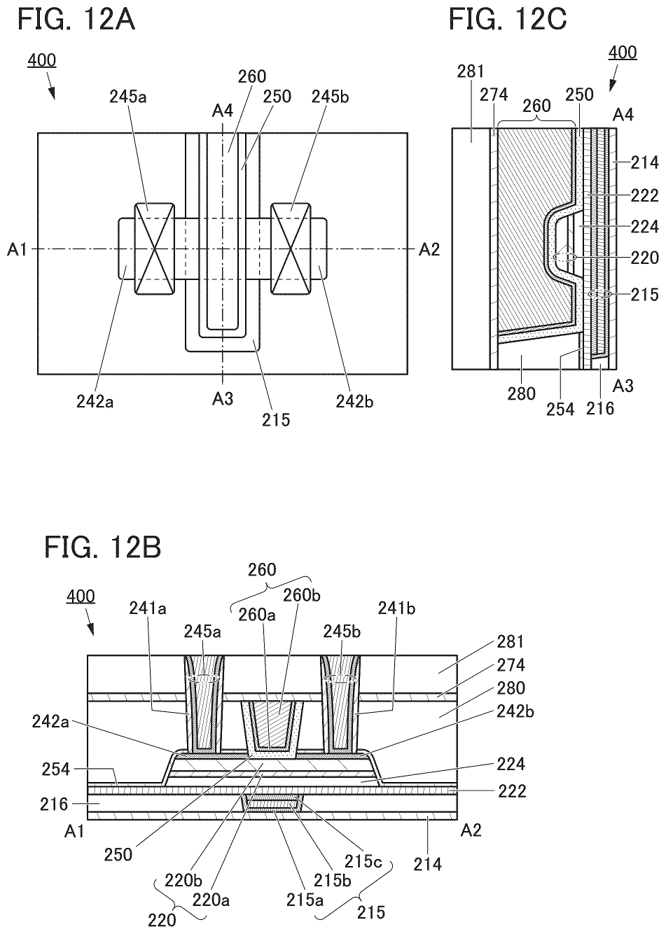

A structure example of the transistor 400 is described as an example of an OS transistor that can be used as to the transistor 200. FIG. 12A, FIG. 12B, and FIG. 12C are a top view and cross-sectional views of the transistor 400 and the periphery of the transistor 400. Note that the structure of the transistor applicable to the transistor 200 is not limited to the structure example of the transistor described in this embodiment.

FIG. 12A is the top view of the transistor 400. FIG. 12B and FIG. 12C are the cross-sectional views of the transistor 400. Here, FIG. 12B is a cross-sectional view of a portion indicated by the dashed-dotted line A1-A2 in FIG. 12A, and is a cross-sectional view of the transistor 400 in the channel length direction. FIG. 12C is a cross-sectional view of a portion indicated by the dashed-dotted line A3-A4 in FIG. 12A, and is a cross-sectional view of the transistor 400 in the channel width direction. Note that for simplification of the drawing, some components are not illustrated in the top view in FIG. 12A.

As illustrated in FIG. 12, the transistor 400 includes a metal oxide layer 220a, a metal oxide layer 220b positioned over the metal oxide layer 220a, the conductive layer 242a and the conductive layer 242b positioned to be isolated from each other over the metal oxide layer 220b, an insulating layer 254 positioned over the conductive layer 242a and the conductive layer 242b, and an insulating layer 280 positioned over the insulating layer 254. Each of the insulating layer 280 and the insulating layer 254 includes an opening portion overlapping with a region between the conductive layer 242a and the conductive layer 242b.

The transistor 400 includes a dielectric layer 250 positioned in the opening portion. The dielectric layer 250 includes a region in contact with part of the insulating layer 280, part of the insulating layer 254, part of the conductive layer 242a, part of the conductive layer 242b, and part of the metal oxide layer 220b. In addition, the transistor 400 includes a conductive layer 260 positioned in the opening portion. The conductive layer 260 includes a region overlapping with the metal oxide layer 220b with the dielectric layer 250 therebetween.

Here, as illustrated in FIG. 12B and FIG. 12C, preferably, the top surface of the conductive layer 260 is substantially level with the top surfaces of the dielectric layer 250 and the insulating layer 280. Note that in this specification and the like, the metal oxide layer 220a and the metal oxide layer 220b are sometimes collectively referred to as a metal oxide 220. In this specification, the conductive layer 242a and the conductive layer 242b are sometimes collectively referred to as a conductive layer 242.

Note that the conductive layer 260 corresponds to the conductive layer 201 of the transistor 200 described in the above embodiment, and the metal oxide layer 220 corresponds to the semiconductor layer 203. The conductive layer 242a corresponds to the conductive layer 206a, and the conductive layer 242b corresponds to the conductive layer 206b.

In the transistor 400 illustrated in FIG. 12, side surfaces of the conductive layer 242a and the conductive layer 242b on the conductive layer 260 side are substantially perpendicular. Note that the transistor 400 illustrated in FIG. 12 is not limited thereto, and an angle formed between the side surfaces and bottom surfaces of the conductive layer 242a and the conductive layer 242b may be greater than or equal to 10° and less than or equal to 80°, preferably greater than or equal to 30° and less than or equal to 60°. The side surfaces of the conductive layer 242a and the conductive layer 242b may have a plurality of surfaces.

As illustrated in FIG. 12, the insulating layer 254 is preferably provided between the insulating layer 280 and each of an insulating layer 224, the metal oxide layer 220a, the metal oxide layer 220b, the conductive layer 242a, and the conductive layer 242b. As illustrated in FIG. 12B and FIG. 12C, the insulating layer 254 is preferably in contact with the top surface and the side surface of the conductive layer 242a, the top surface and the side surface of the conductive layer 242b, a side surface of the metal oxide layer 220a, a side surface of the metal oxide layer 220b, a side surface of the insulating layer 224, and an insulating layer 222.

In the transistor 400, two layers of the metal oxide layer 220a and the metal oxide layer 220b are stacked in and around a region where a channel is formed (hereinafter, also referred to a channel formation region); however, the present invention is not limited thereto. For example, a single-layer structure of the metal oxide layer 220b or a stacked-layer structure of three or more layers may be employed. Alternatively, each of the metal oxide layer 220a and the metal oxide layer 220b may have a stacked-layer structure of two or more layers.

The conductive layer 260 functions as a gate electrode of the transistor 400, and the conductive layer 242a and the conductive layer 242b function as a source electrode and a drain electrode. As described above, the conductive layer 260 is formed to be embedded in an opening portion of the insulating layer 280 and the region interposed between the conductive layer 242a and the conductive layer 242b. Here, the positions of the conductive layer 260, the conductive layer 242a, and the conductive layer 242b are selected in a self-aligned manner with respect to the opening portion of the insulating layer 280. That is, in the transistor 400, the gate electrode can be positioned between the source electrode and the drain electrode in a self-aligned manner. Thus, the conductive layer 260 can be formed without an alignment margin, resulting in a reduction in the area occupied by the transistor 400. Accordingly, the degree of integration of the semiconductor device can be increased.

As illustrated in FIG. 12, the conductive layer 260 preferably includes a conductive layer 260a provided on the inner side of the dielectric layer 250 and a conductive layer 260b provided to be embedded on the inner side of the conductive layer 260a. In this embodiment, although the conductive layer 260 has a stacked-layer structure of two layers, the present invention is not limited thereto. For example, the conductive layer 260 may have a single-layer structure or a stacked-layer structure of three or more layers.

The transistor 400 preferably includes an insulating layer 214; an insulating layer 216 positioned over the insulating layer 214; a conductive layer 215 positioned to be embedded in the insulating layer 216; the insulating layer 222 positioned over the insulating layer 216 and the conductive layer 215; and the insulating layer 224 positioned over the insulating layer 222. The metal oxide layer 220a is preferably positioned over the insulating layer 224.

The conductive layer 215 serves as a back gate electrode. The conductive layer 215 corresponds to the conductive layer 205 of the transistor 400 described in the above embodiment. The insulating layer 222 and the insulating layer 224 correspond to the dielectric layer 204. The insulating layer 222 and the insulating layer 224 function as a gate insulating film on the back gate electrode side.

An insulating layer 274 and an insulating layer 281 functioning as interlayer films are preferably positioned over the transistor 400. Here, the insulating layer 274 is preferably provided in contact with the top surfaces of the conductive layer 260, the dielectric layer 250, and the insulating layer 280.

The insulating layer 214, the insulating layer 222, the insulating layer 254, and the insulating layer 274 preferably have a function of inhibiting diffusion of hydrogen (e.g., at least one of a hydrogen atom, a hydrogen molecule, and the like). Alternatively, the insulating layer 214, the insulating layer 222, the insulating layer 254, and the insulating layer 274 preferably have a function of inhibiting diffusion of oxygen (e.g., at least one of an oxygen atom, an oxygen molecule, and the like). For example, the insulating layer 214, the insulating layer 222, the insulating layer 254, and the insulating layer 274 preferably have lower hydrogen permeability than the insulating layer 224, the dielectric layer 250, and the insulating layer 280. For example, the insulating layer 214 and the insulating layer 274 preferably have lower oxygen permeability than the insulating layer 216, the insulating layer 224, the dielectric layer 250, and the insulating layer 280. In particular, the insulating layer 222 and the insulating layer 254 preferably have a function of inhibiting diffusion of hydrogen and oxygen.

Here, the insulating layer 216, the insulating layer 224, the metal oxide layer 220, the dielectric layer 250, the insulating layer 280, and the like are isolated from the outside by the insulating layer 214 and the insulating layer 274. This can inhibit entry of oxygen and impurities such as hydrogen from the outside into the insulating layer 216, the insulating layer 224, the metal oxide layer 220, the dielectric layer 250, the insulating layer 280, and the like. Furthermore, diffusion of impurities such as hydrogen contained in the insulating layer 216, the insulating layer 224, the metal oxide layer 220, the dielectric layer 250, the insulating layer 280, and the like to the outside can be inhibited. Thus, a change in the concentrations of impurities and oxygen in the layers interposed between the insulating layer 214 and the insulating layer 274 can be inhibited.

A conductive layer 245 (a conductive layer 245a and a conductive layer 245b) that is electrically connected to the transistor 400 and functions as a contact plug is preferably provided. Note that an insulating layer 241 (an insulating layer 241a and an insulating layer 241b) is provided in contact with a side surface of the conducting layer 245 functioning as a contact plug. In other words, the insulating layer 241 is provided in contact with the inner wall of the opening portion in the insulating layer 254, the insulating layer 280, the insulating layer 274, and the insulating layer 281. In addition, a structure may be employed in which a first conductive layer of the conductive layer 245 is provided in contact with a side surface of the insulating layer 241 and a second conductive layer of the conductive layer 245 is provided on the inner side of the first conductive layer. Here, the top surface of the conductive layer 245 and the top surface of the insulating layer 281 can be substantially level with each other. Note that although the transistor 400 having a structure in which the first conductive layer of the conductive layer 245 and the second conductive layer of the conductive layer 245 are stacked is illustrated, the present invention is not limited thereto. For example, the conductive layer 245 may have a single-layer structure or a stacked-layer structure of three or more layers. In the case where a component has a stacked-layer structure, layers may be distinguished by ordinal numbers given corresponding to the formation order.

In the transistor 400, an oxide semiconductor, which is a kind of a metal oxide, is preferably used for the metal oxide layer 220 (the metal oxide layer 220a and the metal oxide layer 220b) including a channel formation region. For example, as the metal oxide layer 220, it is preferable to use a metal oxide having a band gap of higher than or equal to 2 eV, preferably higher than or equal to 2.5 eV.

The metal oxide preferably contains at least indium (In) or zinc (Zn). In particular, indium (In) and zinc (Zn) are preferably contained. In addition to them, an element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). The element M further preferably contains one or both of Ga and Sn.

Furthermore, at least one of hydrogen (H), nitrogen (N), phosphorus (P), fluorine (F), chlorine (Cl), a noble gas, and the like may be added to the metal oxide. Accordingly, carriers are likely to be generated in the metal oxide layer 220, so that a normally-on transistor can be easily achieved.

In addition, the metal oxide layer 220b sometimes has a smaller thickness in a region not overlapping with the conductive layer 242 than in a region overlapping with the conductive layer 242. The thin region is formed when part of the top surface of the metal oxide layer 220b is removed at the time of forming the conductive layer 242a and the conductive layer 242b. When a conductive film to be the conductive layer 242 is formed, a low-resistance region is sometimes formed on the top surface of the metal oxide layer 220b in the vicinity of the interface with the conductive film. Removing the low-resistance region positioned between the conductive layer 242a and the conductive layer 242b on the top surface of the metal oxide layer 220b in the above manner can prevent unintentional formation of the channel in the region.

Next, a detailed structure of the transistor 400 is described.

The conductive layer 215 is positioned to include a region overlapping with the metal oxide layer 220 and the conductive layer 260. Furthermore, the conductive layer 215 is preferably provided to be embedded in the insulating layer 216.

The conductive layer 215 includes a conductive layer 215a, a conductive layer 215b, and a conductive layer 215c. The conductive layer 215a is provided in contact with the bottom surface and the side wall of an opening portion provided in the insulating layer 216. The conductive layer 215b is provided to be embedded in a depressed portion formed by the conductive layer 215a. Here, the top surface of the conductive layer 215b is lower in level than the top surface of the conductive layer 215a and the top surface of the insulating layer 216. The conductive layer 215c is provided in contact with the top surface of the conductive layer 215b and the side surface of the conductive layer 215a. Here, the top surface of the conductive layer 215c is substantially level with the top surface of the conductive layer 215a and the top surface of the insulating layer 216. That is, the conductive layer 215b is surrounded by the conductive layer 215a and the conductive layer 215c.

Note that in this specification and the like, the expression “substantially level with” indicates a structure having the same level from a reference surface (e.g., a flat surface such as a substrate surface) in a cross-sectional view. For example, in a manufacturing process of the semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. In addition, the expression “substantially level with” includes the case of being level with each other. Note that in the case where surfaces of a plurality of layers are exposed, the plurality of layers are not level with each other in some cases, depending on a treatment apparatus, a treatment method, or a material of the treated surfaces in the CMP treatment. This case is also regarded as “substantially level with” in this specification and the like. For example, the expression “substantially level with” includes the case where two layers (here, given as a first layer and a second layer) having different two levels with respect to the reference surface are included, and the difference between the top-surface level of the first layer and the top-surface level of the second layer is less than or equal to 20 nm.

The conductive layer 215a and the conductive layer 215c are preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 215a and the conductive layer 215c are preferably formed using a conductive material having a function of inhibiting diffusion of oxygen (e.g., at least one of an oxygen atom, an oxygen molecule, and the like).

When the conductive layer 215a and the conductive layer 215c are formed using a conductive material having a function of inhibiting diffusion of hydrogen, impurities such as hydrogen contained in the conductive layer 215b can be inhibited from diffusing into the metal oxide layer 220. That is, excessive supply of impurities into the metal oxide layer 220 can be prevented. Furthermore, impurities such as hydrogen contained in the metal oxide layer 220, the insulating layer 224, and the like can be inhibited from diffusing to the outside through the conductive layer 215. Thus, a change in the concentration of impurities in the metal oxide layer 220 can be inhibited.

When the conductive layer 215a and the conductive layer 215c are formed using a conductive material having a function of inhibiting diffusion of oxygen, a phenomenon where the conductivity of the conductive layer 215b is lowered because of oxidation can be inhibited. As the conductive material having a function of inhibiting diffusion of oxygen, for example, titanium, titanium nitride, tantalum, tantalum nitride, ruthenium, ruthenium oxide, or the like is preferably used. Thus, the conductive layer 215a is a single layer or a stacked layer of the above conductive materials. For example, titanium nitride is used for the conductive layer 215a.

A conductive material containing tungsten, copper, or aluminum as its main component is preferably used for the conductive layer 215b. For example, tungsten is used for the conductive layer 215b.

Note that in the case where the insulating layer 222 has a function of inhibiting diffusion of oxygen, the phenomenon where the conductivity of the conductive layer 215b is lowered because of oxidation can be inhibited even without the conductive layer 215c in some cases. Thus, the conductive layer 215 may have a stacked-layer structure of the conductive layer 215a and the conductive layer 215b. Here, the top surface of the conductive layer 215b is substantially level with the top surface of the conductive layer 215a and the top surface of the insulating layer 216.

The conductive layer 260 sometimes functions as a first gate (also referred to as top gate) electrode. The conductive layer 215 sometimes functions as a second gate (also referred to as bottom gate) electrode.

The conductive layer 215 is preferably provided to be larger than the channel formation region in the metal oxide layer 220. In particular, it is preferable that the conductive layer 215 extend beyond an end portion of the metal oxide layer 220 that intersects with the channel width direction, as illustrated in FIG. 12C. In other words, the conductive layer 215 and the conductive layer 260 preferably overlap with each other with the insulating layer positioned therebetween, in a region outside the side surface of the metal oxide layer 220 in the channel width direction.

With the above structure, the channel formation region of the metal oxide layer 220 can be electrically surrounded by electric fields of the conductive layer 260 functioning as the first gate electrode and electric fields of the conductive layer 215 functioning as the second gate electrode.

As illustrated in FIG. 12C, the conductive layer 215 can also function as a wiring. Note that a conductive layer functioning as a wiring may be provided separately and the conductive layer may electrically connect to the conductive layer 215.

The insulating layer 214 preferably functions as a barrier insulating film that inhibits the entry of impurities such as water or hydrogen to the transistor 400 from the substrate side. The insulating layer 214 preferably functions as a barrier insulating film that inhibits diffusion of impurities such as water or hydrogen to the outside from the transistor 400 side.

Accordingly, it is preferable to use, for the insulating layer 214, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

For example, aluminum oxide, silicon nitride, or the like is preferably used for the insulating layer 214. Accordingly, it is possible to inhibit diffusion of impurities such as water or hydrogen into the transistor 400 side from the substrate side through the insulating layer 214. Alternatively, impurities such as water or hydrogen contained in the transistor 400 side can be inhibited from passing through the insulating layer 214 and being diffused to the outside.

The permittivity of each of the insulating layer 216, the insulating layer 280, and the insulating layer 281 functioning as an interlayer film is preferably lower than that of the insulating layer 214. When a material with a low permittivity is used for an interlayer film, the parasitic capacitance generated between wirings can be reduced. For the insulating layer 216, the insulating layer 280, and the insulating layer 281, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate, for example.

It is preferable that oxygen be less likely to be released from the insulating layer 224 in contact with the metal oxide layer 220 by heating. In this specification, oxygen that is released by heating is referred to as excess oxygen in some cases. For example, silicon oxide, silicon nitride, or the like is used as appropriate for the insulating layer 224. When oxygen is supplied to the metal oxide layer 220, oxygen vacancies in the metal oxide layer 220 are reduced, so that the transistor 400 is likely to be a normally-off transistor. When an insulating layer containing a small amount of excess oxygen is provided in contact with the metal oxide layer 220, reduction in oxygen vacancies in the metal oxide layer 220 is inhibited.

The insulating layer 224 preferably contains impurities such as hydrogen. For example, when oxygen vacancies and hydrogen in the metal oxide layer 220 are bonded to each other, carriers are likely to be generated in the metal oxide layer 220; thus, a normally-on transistor can be easily obtained.

Meanwhile, when an oxide that releases part of oxygen by heating is used for the insulating layer 224, the transistor is likely to be a normally-off transistor. An oxide that releases oxygen by heating is an oxide in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C. or 100° C. to 400° C.

The amount of released oxygen in the insulating layer 224 is preferably lower than 1.0×10¹⁹ atoms/cm³, further preferably lower than 1.0×10¹⁸ atoms/cm³ in order to make the transistor 400 less likely to have normally-off characteristics.

Like the insulating layer 214 and the like, the insulating layer 222 preferably functions as a barrier insulating film that inhibits the entry of impurities such as water or hydrogen into the transistor 400 from the substrate side. For example, the insulating layer 222 preferably has a lower hydrogen permeability than the insulating layer 224. When the insulating layer 224, the metal oxide layer 220, the dielectric layer 250, and the like are surrounded by the insulating layer 222, the insulating layer 254, and the insulating layer 274, entry of impurities such as water or hydrogen into the transistor 400 from the outside can be inhibited. In addition, impurities such as water or hydrogen contained in the insulating layer 224 and the like on the transistor 400 side can be inhibited from being diffused to the outside.

It is preferable that the insulating layer 222 have a function of inhibiting diffusion of oxygen (e.g., at least one of an oxygen atom, an oxygen molecule, and the like). The insulating layer 222 preferably has a function of inhibiting diffusion of oxygen and impurities, in which case diffusion of oxygen from the outside to the transistor 400 side can be reduced.

As the insulating layer 222, an insulating layer containing an oxide of one or both of aluminum and hafnium, which is an insulating material, is preferably used. As the insulating layer containing an oxide of one or both of aluminum and hafnium, aluminum oxide, hafnium oxide, an oxide containing aluminum and hafnium (hafnium aluminate), or the like is preferably used. In the case where the insulating layer 222 is formed using such a material, the insulating layer 222 functions as a layer inhibiting release of impurities such as hydrogen from the metal oxide layer 220 and entry of oxygen into the metal oxide layer 220 from the periphery of the transistor 400.

Alternatively, aluminum oxide, bismuth oxide, germanium oxide, niobium oxide, silicon oxide, titanium oxide, tungsten oxide, yttrium oxide, or zirconium oxide may be added to these insulating layers, for example. Alternatively, these insulating layers may be subjected to nitriding treatment. Silicon oxide, silicon oxynitride, or silicon nitride may be stacked over the insulating layer. For example, a three-layer structure in which silicon nitride, silicon oxide, and aluminum oxide are stacked in this order can be used as the insulating layer 222.

The insulating layer 222 may be a single layer or a stacked layer formed using an insulating layer containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST). As miniaturization and high integration of transistors progress, a problem such as leakage current may arise because of a thinner gate insulating film. When a high-k material is used for an insulating layer functioning as the gate insulating film, a gate potential at the time of an operation of the transistor can be reduced while the physical thickness is maintained.

Note that the insulating layer 222 and the insulating layer 224 may each have a stacked-layer structure of two or more layers. In that case, without limitation to a stacked-layer structure formed of the same material, a stacked-layer structure formed of different materials may be employed. For example, an insulating layer similar to the insulating layer 224 may be provided below the insulating layer 222.

Note that the metal oxide layer 220 preferably has a stacked-layer structure of a plurality of oxide layers that differ in the atomic ratio of metal atoms. For example, in the case where the metal oxide layer 220 contains at least indium (In) and the element M, the proportion of the number of atoms of the element M contained in the metal oxide layer 220a to the number of atoms of all elements that constitute the metal oxide layer 220a is preferably higher than the proportion of the number of atoms of the element M contained in the metal oxide layer 220b to the number of atoms of all elements that constitute the metal oxide layer 220b. In addition, the atomic ratio of the element M to In in the metal oxide layer 220a is preferably higher than the atomic ratio of the element M to In in the metal oxide layer 220b.

The energy of the conduction band minimum of the metal oxide layer 220a is preferably higher than the energy of the conduction band minimum of the metal oxide layer 220b. In other words, the electron affinity of the metal oxide layer 220a is preferably smaller than the electron affinity of the metal oxide layer 220b.

Here, the energy level of the conduction band minimum changes gradually at a junction portion between the metal oxide layer 220a and the metal oxide layer 220b. In other words, the energy level of the conduction band minimum at the junction portion between the metal oxide layer 220a and the metal oxide layer 220b continuously changes or is continuously connected. This can be achieved by decrease in the density of defect states in a mixed layer formed at the interface between the metal oxide layer 220a and the metal oxide layer 220b.

Specifically, when the metal oxide layer 220a and the metal oxide layer 220b contain the same element (as a main component) in addition to oxygen, a mixed layer with a low density of defect states can be formed. For example, in the case where the metal oxide layer 220b is In—Ga—Zn oxide, as the metal oxide layer 220a, In—Ga—Zn oxide, Ga—Zn oxide, gallium oxide, or the like may be used.

Specifically, as the metal oxide layer 220a, a metal oxide having In:Ga:Zn=1:3:4 [atomic ratio] or a composition in the neighborhood thereof, or 1:1:0.5 [atomic ratio] or a composition in the neighborhood thereof is used. As the metal oxide layer 220b, a metal oxide having a composition of In:Ga:Zn=1:1:1 [atomic ratio] or a composition in the neighborhood thereof, In:Ga:Zn=4:2:3 [atomic ratio] or a composition in the neighborhood thereof, or 3:1:2 [atomic ratio] or a composition in the neighborhood thereof is used.

At this time, the metal oxide layer 220b serves as a main carrier path. When the metal oxide layer 220a has the above structure, the density of defect states at the interface between the metal oxide layer 220a and the metal oxide layer 220b can be made low. Thus, the influence of interface scattering on carrier conduction is small, and the transistor 400 can have high on-state current and high frequency characteristics.

The conductive layer 242 (the conductive layer 242a and the conductive layer 242b) functioning as the source electrode and the drain electrode is provided over the metal oxide layer 220b. For the conductive layer 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen.

When the conductive layer 242 is provided in contact with the metal oxide layer 220, the oxygen concentration of the metal oxide layer 220 in the vicinity of the conductive layer 242 sometimes decreases. In addition, a metal compound layer that contains the metal contained in the conductive layer 242 and the component of the metal oxide layer 220 is sometimes formed in the metal oxide layer 220 in the vicinity of the conductive layer 242. In such a case, the carrier concentration of the region in the metal oxide layer 220 in the vicinity of the conductive layer 242 increases, and the region becomes a low-resistance region.

Here, the region between the conductive layer 242a and the conductive layer 242b is formed to overlap with the opening portion of the insulating layer 280. Accordingly, the conductive layer 260 can be formed in a self-aligned manner between the conductive layer 242a and the conductive layer 242b.

The dielectric layer 250 functions as a gate insulating film. The dielectric layer 250 is preferably positioned in contact with the top surface of the metal oxide layer 220b. The dielectric layer 250 corresponds to the dielectric layer 202 of the transistor 200. Thus, the material that can have ferroelectricity described in the above embodiment is used for the dielectric layer 250. In particular, a material that can have ferroelectricity is used.

Although FIG. 12 illustrates the conductive layer 260 having a two-layer structure, the conductive layer 260 may have a single-layer structure or a stacked-layer structure of three or more layers.

As the conductive layer 260a, a conductive layer having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom is preferably used. Alternatively, the conductive layer 260a is preferably formed using a conductive material having a function of inhibiting diffusion of oxygen (e.g., at least one of an oxygen atom, an oxygen molecule, and the like).

When the conductive layer 260a has a function of inhibiting diffusion of oxygen, it is possible to inhibit reduction of the conductivity due to oxidation of the conductive layer 260b by oxygen contained in the dielectric layer 250. As the conductive material having a function of inhibiting diffusion of oxygen, for example, tantalum, tantalum nitride, ruthenium, ruthenium oxide, or the like is preferably used.

A conductive material containing tungsten, copper, or aluminum as its main component is preferably used for the conductive layer 260b. The conductive layer 260 also functions as a wiring and thus is preferably formed using a conductive layer having high conductivity. For example, a conductive material containing tungsten, copper, or aluminum as its main component can be used. The conductive layer 260b may have a stacked-layer structure, for example, a stacked-layer structure of any of the above conductive materials and titanium or titanium nitride.

As illustrated in FIG. 12A and FIG. 12C, the side surface of the metal oxide layer 220 is covered with the conductive layer 260 in a region where the metal oxide layer 220b does not overlap with the conductive layer 242, that is, the channel formation region of the metal oxide layer 220. Accordingly, the electric field of the conductive layer 260 functioning as the first gate electrode is likely to act on the side surface of the metal oxide layer 220. Thus, the on-state current of the transistor 400 can be increased and the frequency characteristics can be improved.

The insulating layer 254 preferably functions as a barrier insulating film that inhibits diffusion of impurities such as water or hydrogen into the insulating layer 280 side from the metal oxide layer 220 side. The insulating layer 254 preferably has lower hydrogen permeability than the insulating layer 224, for example. Furthermore, as illustrated in FIG. 12B and FIG. 12C, the insulating layer 254 is preferably in contact with the top surface and the side surface of the conductive layer 242a, the top surface and the side surface of the conductive layer 242b, the side surfaces of the metal oxide layer 220a and the metal oxide layer 220b, and the insulating layer 224. With such a structure, diffusion of impurities such as hydrogen contained in the metal oxide layer 220 to the outside can be inhibited.

It is also preferable that the insulating layer 254 have a function of inhibiting diffusion of oxygen (e.g., at least one of an oxygen atom, an oxygen molecule, and the like). For example, the insulating layer 254 preferably has lower oxygen permeability than the insulating layer 280 or the insulating layer 224.

An insulating layer containing an oxide of one or both of aluminum and hafnium may be formed as the insulating layer 254, for example. As the insulating layer containing an oxide of one or both of aluminum and hafnium, aluminum oxide, hafnium oxide, an oxide containing aluminum and hafnium (hafnium aluminate), or the like may be used.

The insulating layer 280 is isolated from the insulating layer 224 and the metal oxide layer 220 by the insulating layer 254 having a barrier property against oxygen and impurities such as hydrogen. This can inhibit entry of oxygen and impurities such as hydrogen into the metal oxide layer 220 from the insulating layer 280 side. Thus, excessive supply of oxygen and impurities such as hydrogen to the metal oxide layer 220 is inhibited. Furthermore, diffusion of impurities such as hydrogen contained in the metal oxide layer 220 to the outside can also be inhibited, whereby the transistor 400 can maintain the normally-on characteristics easily. Consequently, the transistor 400 can have favorable electrical characteristics and reliability.

The insulating layer 280 is provided over the insulating layer 224, the metal oxide layer 220, and the conductive layer 242 with the insulating layer 254 therebetween. The insulating layer 280 preferably includes, for example, silicon oxide, silicon oxynitride, silicon nitride oxide, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed.

In the insulating layer 280, excess oxygen is preferably reduced. In addition, the top surface of the insulating layer 280 may be planarized.

Like the insulating layer 214 and the like, the insulating layer 274 preferably functions as a barrier insulating film that inhibits entry of impurities such as water or hydrogen into the insulating layer 280 from the above. As the insulating layer 274, for example, the insulating layer that can be used as the insulating layer 214, the insulating layer 254, and the like is used.

The insulating layer 281 functioning as an interlayer film may be provided over the insulating layer 274. The conductive layer 245a and the conductive layer 245b are positioned in opening portions formed in the insulating layer 281, the insulating layer 274, the insulating layer 280, and the insulating layer 254. The conductive layer 245a and the conductive layer 245b are provided to face each other with the conductive layer 260 interposed therebetween. Note that the top surfaces of the conductive layer 245a and the conductive layer 245b may be level with the top surface of the insulating layer 281.

The insulating layer 241a is provided in contact with the inner wall of the opening portion provided in parts of the insulating layer 281, the insulating layer 274, the insulating layer 280, and the insulating layer 254, and the first conductive layer of the conductive layer 245a is formed in contact with the side surface of the insulating layer 241a. The conductive layer 242a is positioned on at least part of the bottom portion of the opening portion, and the conductive layer 245a is in contact with the conductive layer 242a. Similarly, the insulating layer 241b is provided in contact with the inner wall of the opening portion in the insulating layer 281, the insulating layer 274, the insulating layer 280, and the insulating layer 254, and the first conductive layer of the conductive layer 245b is formed in contact with the side surface of the insulating layer 241b. The conductive layer 242b is positioned on at least part of the bottom portion of the opening portion, and the conductive layer 245b is in contact with the conductive layer 242b.

The conductive layer 245a and the conductive layer 245b are preferably formed using a conductive material containing tungsten, copper, or aluminum as its main component. The conductive layer 245a and the conductive layer 245b may each have a stacked-layer structure.

In the case where the conductive layer 245 has a stacked-layer structure, the aforementioned conductive layer having a function of inhibiting diffusion of impurities such as water or hydrogen is preferably used as the conductive layer in contact with the conductive layer 242, the insulating layer 254, the insulating layer 280, the insulating layer 274, and the insulating layer 281. For example, tantalum, tantalum nitride, titanium, titanium nitride, ruthenium, ruthenium oxide, or the like is preferably used. The conductive material having a function of inhibiting diffusion of impurities such as water or hydrogen can be used as a single layer or stacked layers. The use of the conductive material can inhibit impurities such as water or hydrogen from entering the metal oxide layer 220 through the conductive layer 245a and the conductive layer 245b from a layer above the insulating layer 281. Furthermore, diffusion of impurities such as hydrogen contained in the metal oxide layer 220 to the outside can be inhibited.

As the insulating layer 241a and the insulating layer 241b, for example, the insulating layer that can be used as the insulating layer 254 and the like can be used. Since the insulating layer 241a and the insulating layer 241b are provided in contact with the insulating layer 254, impurities such as water or hydrogen in the insulating layer 280 or the like can be inhibited from entering the metal oxide layer 220 through the conductive layer 245a and the conductive layer 245b. Furthermore, diffusion of impurities such as hydrogen contained in the metal oxide layer 220 to the outside through the conductive layer 245a and the conductive layer 245b can be inhibited.

Although not illustrated, a conductive layer functioning as a wiring may be provided in contact with the top surface of the conductive layer 245a and the top surface of the conductive layer 245b. For the conductive layer functioning as a wiring, a conductive material containing tungsten, copper, or aluminum as its main component is preferably used. Furthermore, the conductive layer may have a stacked-layer structure and may be a stack of any of the above conductive materials and titanium or titanium nitride. Note that the conductive layer may be formed to be embedded in an opening portion provided in an insulating layer.

### <Constituent Material of Transistor>

Constituent materials that can be used for the transistor are described.

### [Substrate]

As a substrate over which the transistor is formed, for example, an insulating layer substrate, a semiconductor substrate, or a conductive layer substrate is used. Examples of the insulating layer substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate in which an insulating layer region is included in the semiconductor substrate, e.g., an SOI (Silicon On Insulator) substrate. Examples of the conductive layer substrate include a graphite substrate, a metal substrate, an alloy substrate, and a conductive resin substrate. Other examples include a substrate including a metal nitride and a substrate including a metal oxide. Other examples include an insulating layer substrate provided with a conductive layer or a semiconductor, a semiconductor substrate provided with a conductive layer or an insulating layer, and a conductive layer substrate provided with a semiconductor or an insulating layer. Alternatively, these substrates provided with elements may be used. Examples of the elements provided over the substrates include a capacitor element, a resistor, a switching element, a light-emitting element, and a memory element.

### [Insulating Layers]

Examples of an insulating layer include an oxide, a nitride, an oxynitride, a nitride oxide, a metal oxide, a metal oxynitride, and a metal nitride oxide, each of which has an insulating property.

As miniaturization and high integration of transistors progress, for example, a problem such as leakage current may arise because of a thinner gate insulating film. When a high-k material is used for the insulating layer functioning as a gate insulating film, the voltage at the time of operation of the transistor can be reduced while the physical thickness is maintained. By contrast, when a material with a low dielectric constant is used for the insulating layer functioning as an interlayer film, parasitic capacitance generated between wirings can be reduced. Thus, a material is preferably selected depending on the function of an insulating layer.

Examples of the insulating layer having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulating layer having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including an oxide semiconductor is surrounded by insulating layers having a function of inhibiting passage of oxygen and impurities such as hydrogen (e.g., the insulating layer 214, the insulating layer 222, the insulating layer 254, and the insulating layer 274), the electrical characteristics of the transistor can be stable. An insulating layer having a function of inhibiting the passage of oxygen and impurities such as hydrogen is formed to have a single-layer structure or a stacked-layer structure including an insulating layer containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulating layer having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

### [Conductive Layer]

For a conductive layer, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen. A semiconductor having high electrical conductivity, typified by polycrystalline silicon containing an impurity element such as phosphorus, or silicide such as nickel silicide may be used.

A plurality of conductive layers formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

This embodiment can be combined as appropriate with any of the other embodiments and the like described in this specification.

### Embodiment 4

In this embodiment, an oxide semiconductor that can be used in the OS transistor described in the above embodiment will be described.

The metal oxide used in the OS transistor preferably contains at least indium or zinc, and further preferably contains indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, an ALD method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

A crystal structure of a film or a substrate can be evaluated with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of a crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is suggested that the In—Ga—Zn oxide film formed at room temperature is in an intermediate state, which is neither a single crystal nor polycrystal nor an amorphous state, and it cannot be concluded that In—Ga—Zn oxide film is in an amorphous state.

### [Structure of Oxide Semiconductor]

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Hence, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing step (what is called thermal budget). Accordingly, the use of the CAAC-OS for the OS transistor can extend the degree of freedom of the manufacturing step.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Hence, the orientation in the whole film is not observed. Accordingly, in some cases, the nc-OS cannot be distinguished from an a-like OS and an amorphous oxide semiconductor, depending on the analysis method. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### [Structure of Oxide Semiconductor]

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing an indium oxide, an indium zinc oxide, or the like as its main component. The second region is a region containing a gallium oxide, a gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated intentionally, for example. Furthermore, in the case where the CAC-OS is formed by a sputtering method, any one or more selected from an inert gas (typically, argon), an oxygen gas, and a nitrogen gas is used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

On the other hand, the second region has a higher insulating property than the first region. In other words, when the second regions are distributed in a metal oxide, leakage current can be inhibited.

Thus, in the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Impurity>

Here, the influence of each impurity in the oxide semiconductor will be described.

When silicon or carbon, which is one of Group 14 elements, is contained in the oxide semiconductor, defect states are formed in the oxide semiconductor. Therefore, in the case where the oxide semiconductor is used for a semiconductor layer of a normally-off transistor, the concentration of silicon or carbon in the oxide semiconductor (the concentration obtained by secondary ion mass spectrometry (SIMS)) is lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Therefore, a normally-on transistor is easily obtained with the use of the oxide semiconductor containing an alkali metal or an alkaline earth metal. Meanwhile, when the oxide semiconductor is used for a semiconductor layer of a normally-off transistor, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, when an oxide semiconductor containing nitrogen is used for a semiconductor, a normally-on transistor is easily obtained. Meanwhile, when the oxide semiconductor is used for a semiconductor layer of a normally-off transistor, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1× 10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Accordingly, when an oxide semiconductor containing hydrogen is used, a normally-on transistor is easily obtained. Meanwhile, when the oxide semiconductor is used for a semiconductor layer of a normally-off transistor, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

This embodiment can be combined as appropriate with any of the other embodiments and the like described in this specification.

### Embodiment 5

In this embodiment, examples of electronic components in which the semiconductor device or the like described in the above embodiments is incorporated will be described.

### <Electronic Component>

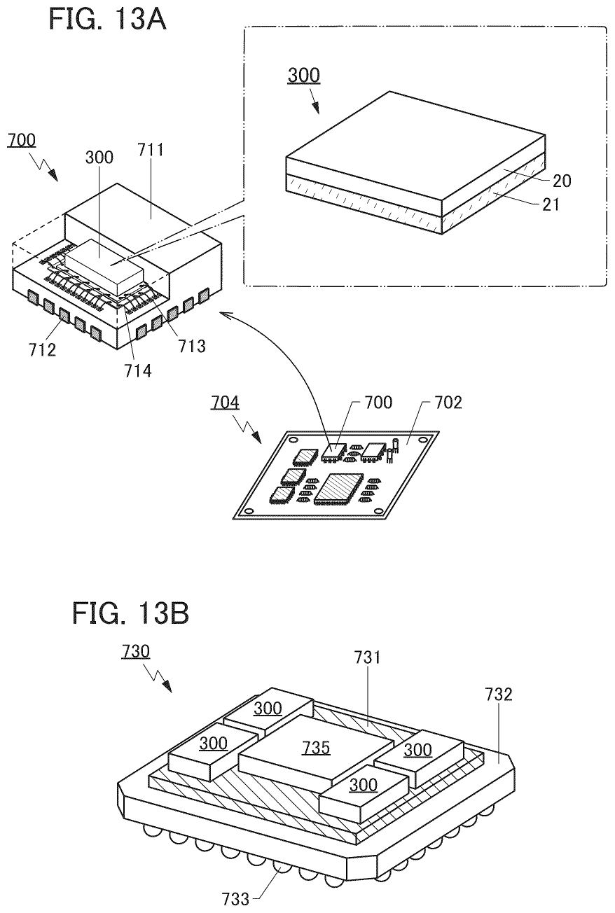

FIG. 13A is a perspective view of an electronic component 700 and a substrate (circuit board 704) on which the electronic component 700 is mounted. The electronic component 700 illustrated in FIG. 13A includes the memory device 300 that is a kind of semiconductor devices in a mold 711. FIG. 13A omits part of the electronic component to show the inside of the electronic component 700. The electronic component 700 includes a land 712 outside the mold 711. The land 712 is electrically connected to an electrode pad 713, and the electrode pad 713 is electrically connected to the memory device 300 via a wire 714. The electronic component 700 is mounted on a printed circuit board 702, for example. A plurality of such electronic components are combined and electrically connected to each other on the printed circuit board 702, which forms the circuit board 704.

The memory device 300 includes the driver circuit 21 and the memory array 20. Alternatively, a plurality of layers of memory arrays 20 may be provided over the driver circuit 21.

FIG. 13B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of memory devices 300 are provided over the interposer 731.

The electronic component 730 using the memory device 300 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a through-silicon via (TSV) can also be used as the through electrode.

A silicon interposer is preferably used as the interposer 731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the memory device 300 and the semiconductor device 735 are preferably the same, for example.

An electrode 733 may be provided on the bottom portion of the package substrate 732 to mount the electronic component 730 on another substrate. FIG. 13B illustrates an example where the electrode 733 is formed of a solder ball. Solder balls are provided in a matrix on the bottom portion of the package substrate 732, whereby a BGA (Ball Grid Array) can be achieved. Alternatively, the electrode 733 may be formed of a conductive pin. When conductive pins are provided in a matrix on the bottom portion of the package substrate 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be combined as appropriate with any of the other embodiments and the like described in this specification.

### Embodiment 6

In this embodiment, application examples of the memory device of one embodiment of the present invention are described.

The memory device of one embodiment of the present invention can be applied to, for example, memory devices of a variety of electronic devices (e.g., information terminals, computers, smartphones, e-book readers, digital still cameras, video cameras, video recording/reproducing devices, navigation systems, game machines, and the like). In addition, the memory device can also be used for image sensors, IoT (Internet of Things), healthcare-related devices, and the like. Note that here, the computers refer not only to tablet computers, laptop computers, and desktop computers, but also to large computers such as server systems.

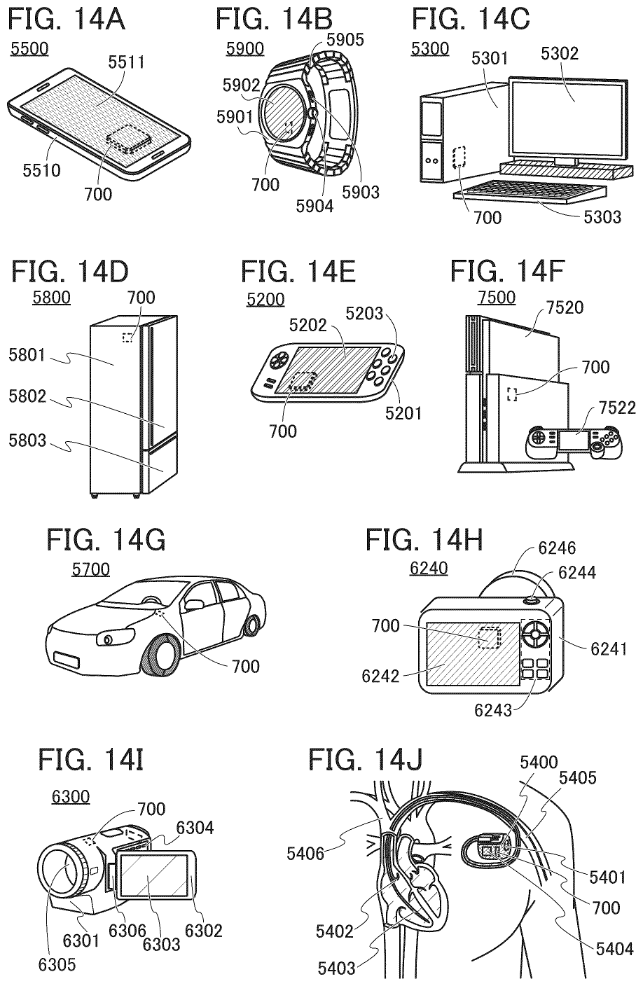

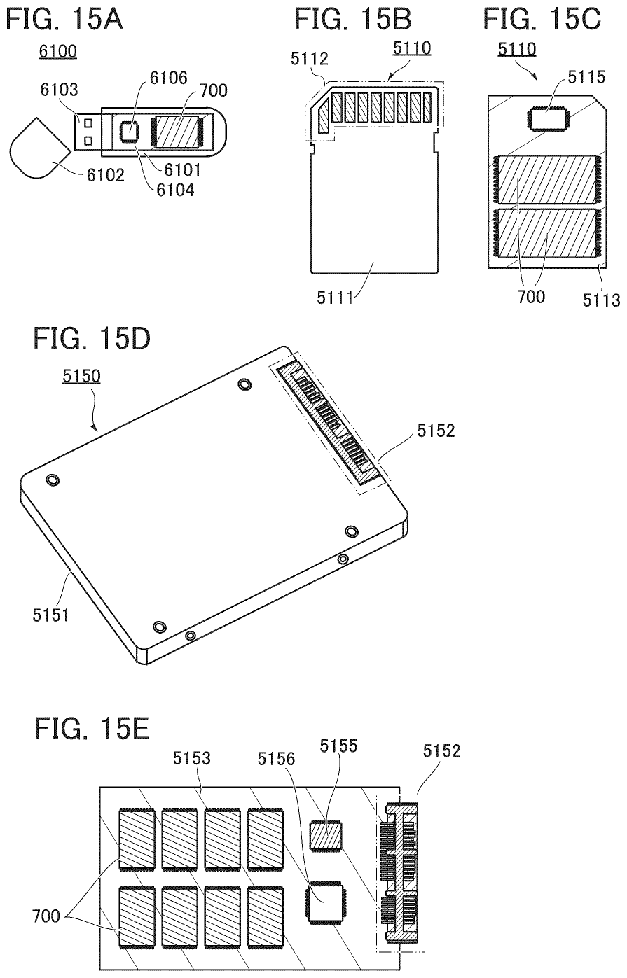

Examples of an electronic device including the memory device of one embodiment of the present invention will be described. Note that FIG. 14A to FIG. 14J and FIG. 15A to FIG. 15E each illustrate a state where the electronic component 700 or the electronic component 730, each of which includes the memory device, is included in an electronic device.

### [Cellular Phone]

An information terminal 5500 illustrated in FIG. 14A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By applying the memory device of one embodiment of the present invention to the information terminal 5500, the information terminal 5500 can retain a temporary file generated at the time of executing an application (e.g., a web browser's cache or the like).

### [Wearable Terminal]

In addition, FIG. 14B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by applying the memory device of one embodiment of the present invention to the wearable terminal.

### [Information Terminal]

In addition, FIG. 14C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application applying the memory device of one embodiment of the present invention to the desktop information terminal 5300.

Note that although the smartphone, the wearable terminal, and the desktop information terminal are respectively illustrated in FIG. 14A to FIG. 14C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

In addition, FIG. 14D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal and the like via the Internet. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, an audiovisual appliance, and the like.

### [Game Machine]

In addition, FIG. 14E illustrates a portable game machine 5200 as an example of a game machine. The portable game machine 5200 includes a housing 5201, a display portion 5202, a button 5203, and the like.

In addition, FIG. 14F illustrates a stationary game machine 7500 as another example of a game machine. The stationary game machine 7500 includes a main body 7520 and a controller 7522. Note that the controller 7522 can be connected to the main body 7520 with or without a wire. Furthermore, although not illustrated in FIG. 14F, the controller 7522 can include a display portion that displays a game image, and an input interface besides a button, such as a touch panel, a stick, a rotating knob, and a sliding knob, for example. Moreover, the shape of the controller 7522 is not limited to that illustrated in FIG. 14F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display device such as a television device, a personal computer display, a game display, or a head-mounted display.

The memory device described in the above embodiments is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, the memory device described in the above embodiments is employed for the portable game machine 5200 or the stationary game machine 7500, so that it is possible to retain a temporary file necessary for arithmetic operation that occurs during game play.

As an example of a game machine, FIG. 14E illustrates a portable game machine. In addition, FIG. 14F illustrates a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), a throwing machine for batting practice installed in sports facilities, and the like.

### [Moving Vehicle]

The memory device described in the above embodiments can be used for a motor vehicle, which is a moving vehicle, and around the driver's seat in a motor vehicle.

FIG. 14G illustrates a motor vehicle 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the motor vehicle 5700. In addition, a memory device showing the above information may be provided around the driver's seat.

In particular, the display device can compensate for the view obstructed by a pillar or the like, blind areas for the driver's seat, and the like by displaying a video from an imaging device (not illustrated) provided for the motor vehicle 5700, which can increase safety. That is, display of an image from an imaging device provided on the outside of the motor vehicle 5700 can fill in blind areas and increase safety.

The semiconductor device described in the above embodiments can temporarily hold information; thus, the memory device can be used to hold temporary data necessary in a system conducting automatic driving, navigation, and risk prediction for the motor vehicle 5700, for example. The display device may be configured to display temporary information regarding navigation, risk prediction, or the like. Moreover, the semiconductor device may be configured to hold a video of a driving recorder provided in the motor vehicle 5700.

Note that although a motor vehicle is described above as an example of a moving vehicle, the moving vehicle is not limited to a motor vehicle. Examples of moving vehicles include a train, a monorail train, a ship, a flying object (a helicopter, an unmanned aircraft (a drone), an airplane, and a rocket), and the like.

### [Camera]

The memory device described in the above embodiments can be employed for a camera. FIG. 14H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, although the camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

When the memory device described in the above embodiments is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The memory device described in the above embodiments can be employed for a video camera.

FIG. 14I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Videos displayed on the display portion 6303 may be changed in accordance with the angle at the joint 6306 between the first housing 6301 and the second housing 6302.

When videos taken by the video camera 6300 are recorded, the videos need to be encoded in accordance with a data recording format. With the use of the above semiconductor device, the video camera 6300 can retain a temporary file generated in encoding.

### [ICD]

The memory device described in the above embodiments can be employed for an implantable cardioverter-defibrillator (ICD).

FIG. 14J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

In addition, the antenna 5404 can receive power, and the battery 5401 is charged with the power. Furthermore, when the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The semiconductor device described in the above embodiments can be employed for a calculator such as a PC (Personal Computer) and an expansion device for an information terminal.

FIG. 15A illustrates, as an example of the expansion device, a portable expansion device 6100 that includes a chip capable of holding information and is externally provided on a PC. The expansion device 6100 can store information using the chip when connected to a PC with a USB (Universal Serial Bus) or the like, for example. Note that FIG. 15A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiments. For example, the substrate 6104 is provided with the electronic component 700 and a controller chip 6106. The USB connector 6103 functions as an interface for connection to an external device.

### [SD Card]

The memory device described in the above embodiments can be employed for an SD card that can be attached to an electronic device such as an information terminal or a digital camera.

FIG. 15B is a schematic external view of an SD card, and FIG. 15C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the electronic components 700 and a controller chip 5115 are attached to the substrate 5113. Note that the circuit structures of the electronic components 700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 700.

When the electronic components 700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The memory device described in the above embodiments can be employed for an SSD (Solid State Drive) that can be attached to an electronic device such as an information terminal.

FIG. 15D is a schematic external view of an SSD, and FIG. 15E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit structures of the electronic components 700, the memory chip 5155, and the controller chip 5156 are not limited to those described above, and the circuit structures can be changed as appropriate according to circumstances. For example, a memory functioning as a work memory may also be provided in the controller chip 5156.

### [Computer]

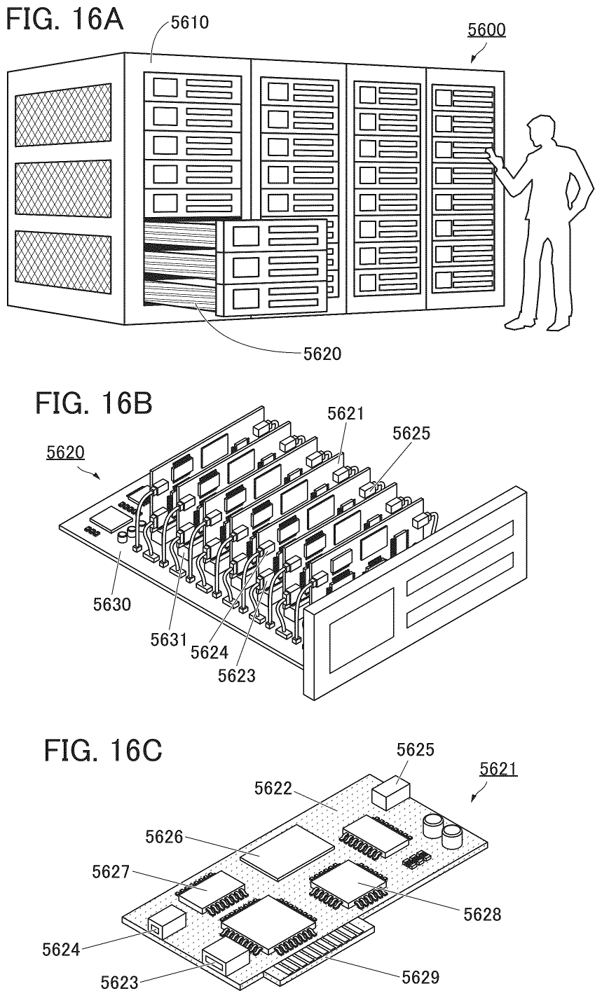

A computer 5600 illustrated in FIG. 16A is an example of a large computer. In the computer 5600, a plurality of rack mount computers 5620 are stored in a rack 5610.

The computer 5620 can have a structure in a perspective view illustrated in FIG. 16B, for example. In FIG. 16B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 16C is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 16C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, a CPU, and the like. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices or the like described above, so that a reduction in size and a reduction in power consumption of the electronic device can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high temperature environment. Thus, the reliability of the electronic devices can be increased.

This embodiment can be combined as appropriate with any of the other embodiments and the like described in this specification.

### REFERENCE NUMERALS

100: semiconductor device, 200: transistor, 201: conductive layer, 202: dielectric layer, 203: semiconductor layer, 204: dielectric layer, 205: conductive layer, 213: channel formation region, 214: insulating layer, 215: conductive layer, 216: insulating layer, 220: metal oxide layer, 222: insulating layer, 224: insulating layer, 241: insulating layer, 242: conductive layer, 245: conductive layer, 250: dielectric layer, 254: insulating layer, 260: conductive layer, 274: insulating layer, 280: insulating layer, 281: insulating layer

1. A memory element comprising a first electrode that comprises a region overlapping with a semiconductor layer with a first insulating layer therebetween and a second electrode that comprises a region overlapping with the semiconductor layer with a second insulating layer therebetween,
wherein the first electrode and the second electrode comprise a region where they overlap with each other with the first insulating layer, the semiconductor layer, and the second insulating layer therebetween,
wherein the semiconductor layer comprises an oxide semiconductor, and
wherein the first insulating layer has anti-ferroelectricity.

2. A memory element comprising a first electrode that comprises a region overlapping with a first region of a semiconductor layer with a first insulating layer therebetween, a second electrode that comprises a region overlapping with the first region with a second insulating layer therebetween, a third electrode electrically connected to a second region of the semiconductor layer, and a fourth electrode electrically connected to a third region of the semiconductor layer,
wherein the first electrode and the second electrode comprise a region where they overlap with each other with the first insulating layer, the first region, and the second insulating layer therebetween,
wherein the semiconductor layer comprises an oxide semiconductor, and
wherein the first insulating layer has anti-ferroelectricity.

3. The memory element according to claim 1,
wherein the semiconductor layer comprises at least one of indium and zinc.

4. The memory element according to claim 1,
wherein the first insulating layer comprises hafnium.

5. The memory element according to claim 4,
wherein the first insulating layer comprises zirconium.

6. The memory element according to claim 1,
wherein the semiconductor layer comprises at least one of hydrogen, nitrogen, phosphorus, fluorine, chlorine, and a noble gas.

7. The memory element according to claim 1,
wherein the memory element is configured to retain multilevel data.

8. A memory device comprising a memory array that comprises a plurality of the memory elements described in claim 1 and a driver circuit.

9. The memory element according to claim 2,
wherein the semiconductor layer comprises at least one of indium and zinc.

10. The memory element according to claim 2,
wherein the first insulating layer comprises hafnium.

11. The memory element according to claim 10,
wherein the first insulating layer comprises zirconium.

12. The memory element according to claim 2,
wherein the semiconductor layer comprises at least one of hydrogen, nitrogen, phosphorus, fluorine, chlorine, and a noble gas.

13. The memory element according to claim 2,
wherein the memory element is configured to retain multilevel data.

14. A memory device comprising a memory array that comprises a plurality of the memory elements described in claim 2 and a driver circuit.
